(19) United States
(12) Patent Application Publication
(10) Pub. No.: US 2011/0041910 A1
(43) Pub. Date: Feb. 24, 2011

(54) PHOTOELECTRIC CONVERSION DEVICE AND MANUFACTURING METHOD THEREOF

(75) Inventors: Akihisa SHIMOMURA, Atsugi (JP); Sho KATO, Atsugi (JP); Yoshikazu HIURA, Atsugi (JP)

Correspondence Address: NIXON PEABODY, LLP, 401 9TH STREET, NW, SUITE 900, WASHINGTON, DC, 20004-2128, US

(73) Assignee: SEMICONDUCTOR ENERGY LABORATORY CO., LTD., Atsugi-shi (JP)

(21) Appl. No.: 12/854,201

(22) Filed: Aug. 11, 2010

(30) Foreign Application Priority Data
Aug. 18, 2009 (JP) 2009-189068

(51) Int. Cl. H01L 31/036; H01L 31/18

(52) U.S. Cl. 136/256; 438/57; 257/E31.002

(57) ABSTRACT

A novel photoelectric conversion device and a manufacturing method thereof are provided. The photoelectric conversion device includes an insulating layer over a light-transmitting base substrate; a single crystal semiconductor layer provided with a plurality of depressions which are filled with the insulating layer; a plurality of first impurity semiconductor layers formed in stripes having one conductivity type and a plurality of second impurity semiconductor layers formed in stripes having a conductivity type which is opposite to the one conductivity type, which are arranged alternately and do not overlap with each other, in a surface layer or over a surface of the single crystal semiconductor layer; first electrodes which are in contact with the first impurity semiconductor layers; and second electrodes which are in contact with the second impurity semiconductor layers.

### BACKGROUND OF THE INVENTION

1. Field of the Invention

The present invention relates to a photoelectric conversion device and a manufacturing method thereof.

2. Description of the Related Art

Global warming has become a serious problem, and the active use of energy sources which will replace fossil fuels has started to spread. In recent years, research and development on photoelectric conversion devices, which are also called solar cells, have become very active, and the market is rapidly expanding.

The photoelectric conversion devices are very attractive power generation means which use inexhaustible sunlight as the energy source and which do not emit carbon dioxide at the time of power generation. However, there are problems under present conditions in that photoelectric conversion efficiency per unit area is not sufficient, that the amount of power generation is affected by the daylight hours, and the like. Accordingly, a long time of around 20 years is needed for recovery of the initial cost. These problems prevent the widespread use of the photoelectric conversion devices for residential use. Thus, an increase in efficiency and a reduction in cost of the photoelectric conversion devices are required.

The photoelectric conversion devices can be manufactured using a silicon-based material or a compound semiconductor material. Most of the photoelectric conversion devices sold in the market are silicon-based solar cells such as bulk silicon solar cells and thin film silicon solar cells. The bulk crystal silicon solar cell which is formed using a single crystal silicon wafer or a polycrystalline silicon wafer has relatively high conversion efficiency. However, a region which is actually utilized for photoelectric conversion is only a part of the silicon wafer in the thickness direction, and the other region only serves as a support which has conductivity. Further, loss of a material used as a cutting margin which is required in cutting out the silicon wafer from an ingot, necessity of a polishing step, and the like are also the factors that prevent a decrease in cost of the bulk silicon solar cells.

On the other hand, thin film silicon solar cells can be formed by forming a silicon thin film using a required amount of silicon by a plasma CVD method or the like. In addition, integration by a laser processing method, a screen printing method, or the like is easy; thus, production costs of the thin film silicon solar cells can be reduced by saving resources, increasing in area, and the like compared with the bulk silicon solar cells. However, the thin film silicon solar cells have a disadvantage in that the photoelectric conversion efficiency is lower than that of the bulk crystal silicon solar cells.

In order to achieve low cost while keeping high photoelectric conversion efficiency, a method for manufacturing solar cells has been proposed in which hydrogen ions are implanted into a crystalline semiconductor and the crystalline semiconductor is cut by heat treatment to obtain a crystalline semiconductor layer which will serve as a photoelectric conversion layer (e.g., see Patent Document 1). The crystalline semiconductor to which ions of a predetermined element are implanted in a layer shape is attached on an insulating layer over a substrate with a conductive adhesive interposed therebetween, and the crystalline semiconductor and the insulating layer are fixed by heat treatment at 300° C. or higher and 500° C. or lower. Then, voids are formed in the region where the ions of the predetermined element are implanted to the crystalline semiconductor in the layer shape by heat treatment at 500° C. or higher and 700° C. or lower, and further the crystalline semiconductor is separated at the voids using a heat strain, so that a crystalline semiconductor layer which serves as a photoelectric conversion layer is formed over the substrate.

As a structure which takes sunlight in a photoelectric conversion device without loss, a back contact structure in which a collection electrode is not formed on a light-receiving surface and so as not to provide shadow loss has been proposed (e.g., see Non Patent Document 1). In this back contact structure, not only semiconductor junction which forms an internal electric field but also all the electrodes are provided on the back side of the light-receiving surface. Only a textured structure or a passivation layer which is used to prevent reflection of light and recombination of carriers is formed on the front surface side; thus, loss due to the structure of a cell is removed as much as possible, and high conversion efficiency is obtained.

A method has also been proposed in which a single crystal silicon wafer whose surface portion is a porous layer is used as a seed layer, a single crystal silicon layer is epitaxially grown, a photoelectric conversion element is formed using the formed single crystal silicon layer, and then the substrate is attached to another substrate and separated at a porous portion (e.g., see Patent Document 2). In the method, the porous layer is formed by anodization of a single crystal wafer, and the single crystal silicon is epitaxially grown over the porous layer a vapor phase method or a liquid phase method. Then, a pattern is formed of a low-resistance material including an n-type or p-type dopant, and an impurity layer having one conductivity type and an electrode are formed by heating. Then, the entire surface is covered with an insulating layer, and then opening is formed in a region other than the electrode which has been formed, and an impurity layer having a conductivity type which is opposite to the one conductivity type is grown by liquid phase epitaxy. The back contact photoelectric conversion device formed in this way is attached to another support substrate with a conductive adhesive, and separated at the porous layer. The separated silicon wafer is used plural times by repeating similar steps.

### [References]

[Patent Document 1] Japanese Published Patent Application No. H10-335683
[Patent Document 2] Japanese Published Patent Application No. H11-214720
[Non-Patent Document] R. A. Sinton, Young Kwark, J. Y. Gan, and Richard M. Swanson, “27.5-Percent Silicon Concentrator Solar Cells”, IEEE Electron Device Lett., vol. EDL-7, no. 10, pp. 567-569, October 1986

In a conventional photoelectric conversion device in which a thin layer of a silicon wafer is used, a conductive adhesive is used for attaching a substrate which serves as a support and the silicon semiconductor layer. A module which is formed using such a photoelectric conversion device includes a stack of several kinds of materials which have different properties, and therefore, a structure resistant to bending or twist is required. In addition, in terms of resistance to environmental stress, it is an important object to ensure resistance to bending or twist which is particularly caused by a temperature change.

Further, since a filler metal used for the conductive adhesive has almost no transmittance in an absorption wavelength range of the photoelectric conversion device, a structure is employed in which a light-receiving surface is not the support substrate side but the front surface side of the semiconductor layer. This structure is referred to as a substrate type, and the light-receiving surface is sealed with a light-transmitting resin or the like to complete a modular structure. The substrate type has characteristics of thin and light weight, but also has a problem of low resistance to bending, twist, pressing force, or the like. As photoelectric conversion devices on roofs of buildings or the like, superstrate type modules with high mechanical strength, in which the support substrate side receives light, are often used.

On the other hand, a thin film silicon solar cell is easily integrated to form a large area solar cell by a laser processing method, a screen printing method, or the like. In addition, the thin film silicon solar cell of a superstrate type with high mechanical strength is easily formed. However, it is difficult to form a single crystal silicon film having high photoelectric conversion efficiency in a large area in a manner similar to a non-single-crystal silicon film, which is a serious concern.

### SUMMARY OF THE INVENTION

In view of the foregoing problems, an object of one embodiment of the present invention is to provide a photoelectric conversion device of resource saving type making good use of a semiconductor material. Another object of one embodiment of the present invention is to provide a photoelectric conversion device with high mechanical strength and improved photoelectric conversion efficiency. Another object of one embodiment of the present invention is to provide a manufacturing method of the above photoelectric conversion device.

One embodiment of the present invention disclosed in this specification is a photoelectric conversion device and a manufacturing method thereof in which a back contact cell which performs photoelectric conversion with its single crystal semiconductor layer is provided over a light-transmitting insulating substrate, and in which a light-receiving surface is on the light-transmitting insulating substrate side.

One embodiment of the present invention disclosed in this specification is a photoelectric conversion device including a light-transmitting base substrate; a light-transmitting insulating layer over the light-transmitting base substrate; a single crystal semiconductor layer over the light-transmitting insulating layer; a plurality of first impurity semiconductor layers having one conductivity type provided in stripes in a surface layer of the single crystal semiconductor layer; a plurality of second impurity semiconductor layers which are arranged alternately with the first impurity semiconductor layers and do not overlap with the first impurity semiconductor layers, the plurality of second impurity semiconductor layers having a conductivity type which is opposite to the one conductivity type provided in stripes; first electrodes in contact with the first impurity semiconductor layers; and second electrodes in contact with the second impurity semiconductor layers. In the photoelectric conversion device, a first plurality of depressions are formed on the single crystal semiconductor layer on the side where the single crystal semiconductor layer is in contact with the light-transmitting insulating layer.

Note that “single crystal” or “single-crystal” in this specification refers to a crystal which has aligned crystal faces and aligned crystal axes and in which atoms or molecules included in the single crystal are arranged in a spatially ordered manner. However, although single crystals are structured by orderly arranged atoms. single crystals may include disorder such as a lattice defect in which the alignment is partially disordered or intended or unintended lattice distortion.

Ordinal numbers such as first and second which are used in this specification are given for convenience in order to distinguish elements, and they are not intended to limit the number of elements, the arrangement, nor the order of the steps.

One embodiment of the present invention disclosed in this specification is a photoelectric conversion device including a light-transmitting base substrate; a light-transmitting insulating layer over the light-transmitting base substrate; a single crystal semiconductor layer over the light-transmitting insulating layer; a plurality of first impurity semiconductor layers having one conductivity type provided in stripes over a surface of the single crystal semiconductor layer; a plurality of second impurity semiconductor layers which are arranged alternately with the first impurity semiconductor layers and do not overlap with the first impurity semiconductor layers, the plurality of second impurity semiconductor layers having a conductivity type which is opposite to the one conductivity type provided in stripes; first electrodes in contact with the first impurity semiconductor layers; and second electrodes in contact with the second impurity semiconductor layers. In the photoelectric conversion device, a first plurality of depressions are formed on the single crystal semiconductor layer on the side where the single crystal semiconductor layer is in contact with the insulating layer.

Here, the first plurality of depressions formed on the single crystal semiconductor layer are filled with the insulating layer. In addition, a second plurality of depressions may be formed on the surface layer in the single crystal semiconductor layer. The first and/or second depression has a circular shape at a surface of the single crystal semiconductor layer and an internal diameter which gradually decreases. Note that the surface layer means a surface and its vicinity of the side of the single crystal semiconductor layer which is opposite to the side in contact with the insulating layer.

Light which enters the single crystal semiconductor layer through the light-transmitting base substrate is repeatedly scattered by a light-trapping effect which is caused by the first plurality of depressions and/or the second plurality of depressions, whereby photo-carriers can be efficiently generated.

One embodiment of the present invention disclosed in this specification is a method for manufacturing a photoelectric conversion device in which a light-transmitting base substrate and a single crystal semiconductor substrate provided with an embrittlement layer are used, which including forming a semiconductor layer including an amorphous region and a single crystal semiconductor layer over the single crystal semiconductor substrate; selectively etching the amorphous region in the semiconductor layer; forming an insulating layer over a surface of the single crystal semiconductor layer so as to cover the surface of the single crystal semiconductor layer; bonding the single crystal semiconductor substrate to the light-transmitting base substrate with the insulating layer interposed between the single crystal semiconductor substrate and the light-transmitting base substrate; dividing the single crystal semiconductor substrate at the embrittlement layer to provide a stack including the insulating layer and a first single crystal semiconductor layer in this order over the base substrate; performing planarizing treatment on a surface of the first single crystal semiconductor layer; forming a second single crystal semiconductor layer over the stack; forming a plurality of first impurity semiconductor layers having one conductivity type in stripes in a surface layer of or over a surface of the second single crystal semiconductor layer; forming a plurality of second impurity semiconductor layers having a conductivity type which is opposite to the one conductivity type in stripes which are arranged alternately with the first impurity semiconductor layers and do not overlap with the first impurity semiconductor layers; forming first electrodes which are in contact with the first impurity semiconductor layer, and forming second electrodes which are in contact with the second impurity semiconductor layers.

Note that an “embrittlement layer” in this specification refers to a region and its vicinity at which a single crystal semiconductor substrate is divided into a single crystal semiconductor layer and a separation substrate (a single crystal semiconductor substrate which has been separated from the single crystal semiconductor layer bonded to the insulating layer) by a division step. The states of the “embrittlement layer” vary according to a method for forming the “embrittlement layer.” For example, the “embrittlement layer” refers to a weakened region where the crystal structure is locally disordered. Note that a region between the surface of the single crystal semiconductor substrate and the “embrittlement layer” is weakened to some extent in some cases. However, the “embrittlement layer” in this specification refers to a region and its vicinity at which the single crystal semiconductor substrate is divided after being attached to another substrate.

Further, after the formation of the second single crystal semiconductor layer, a step of forming a semiconductor layer having an amorphous region and a single crystal semiconductor layer over the second single crystal semiconductor layer and a step of selectively etching the amorphous region may be performed so that a plurality of depressions are formed on a surface layer of the second single crystal semiconductor layer.

According to one embodiment of the present invention, a high-efficiency and resource-saving photoelectric conversion device with high mechanical strength in which a transparent insulating substrate is used as a support substrate can be provided. In addition, a manufacturing method of the photoelectric conversion device can be provided.

### BRIEF DESCRIPTION OF THE DRAWINGS

FIGS. 1A and 1B are cross-sectional schematic views illustrating a photoelectric conversion device according to one embodiment of the present invention.

FIGS. 2A to 2C are cross-sectional views illustrating a manufacturing method of a photoelectric conversion device according to one embodiment of the present invention.

FIGS. 3A to 3C are cross-sectional views illustrating a manufacturing method of a photoelectric conversion device according to one embodiment of the present invention.

FIGS. 4A to 4C are cross-sectional views illustrating a manufacturing method of a photoelectric conversion device according to one embodiment of the present invention.

FIGS. 5A and 5B are cross-sectional views illustrating a manufacturing method of a photoelectric conversion device according to one embodiment of the present invention.

FIGS. 6A and 6B are cross-sectional views illustrating a manufacturing method of a photoelectric conversion device according to one embodiment of the present invention.

FIGS. 7A to 7C are cross-sectional views illustrating a manufacturing method of a photoelectric conversion device according to one embodiment of the present invention.

FIG. 8 is a plan view illustrating a photoelectric conversion device according to one embodiment of the present invention.

FIG. 9 is a plan view illustrating a manufacturing method of a photoelectric conversion device according to one embodiment of the present invention.

FIGS. 10A to 10D illustrate examples in which a single crystal semiconductor substrate having a predetermined shape is cut out from a circular single crystal semiconductor substrate according to one embodiment of the present invention.

FIGS. 11A to 11C are cross-sectional views illustrating a manufacturing method of a photoelectric conversion device according to one embodiment of the present invention.

FIGS. 12A and 12B are cross-sectional views illustrating a manufacturing method of a photoelectric conversion device according to one embodiment of the present invention.

FIG. 13 is a cross-sectional view illustrating a manufacturing method of an embrittlement layer according to an alternative embodiment of the present invention.

FIGS. 14A and 14B are cross-sectional views illustrating a manufacturing method of a photoelectric conversion device according to one embodiment of the present invention.

FIGS. 15A and 15B are cross-sectional views illustrating a manufacturing method of a photoelectric conversion device according to one embodiment of the present invention.

FIG. 16 is a graph showing a relationship between a flow ratio of source gases for film formation and a membrane stress according to one embodiment of the present invention.

FIG. 17 is a graph showing a relationship between a film formation temperature and the density of holes which are formed using amorphous regions according to one embodiment of the present invention.

FIG. 18 is an electron microscope photograph of a cross-sectional structure of a sample according to one embodiment of the present invention.

FIGS. 19A and 19B are electron microscope photographs of surface conditions of samples according to one embodiment of the present invention.

FIG. 20 is a graph showing a spectral reflectance of samples according to one embodiment of the present invention.

### DETAILED DESCRIPTION OF THE INVENTION

Hereinafter, embodiments of the present invention are described below with reference to the drawings. Note that the present invention is not limited to the following description and it will be readily appreciated by those skilled in the art that modes and details can be modified in various ways without departing from the spirit and the scope of the present invention. Accordingly, the present invention should not be construed as being limited to the description of the embodiments to be given below. Note that in a structure of the present invention to be described below, the same reference numerals are used to denote the same components in different drawings.

### Embodiment 1

One embodiment of the present invention relates to a photoelectric conversion device having a single crystal semiconductor layer. In the photoelectric conversion device, a light-transmitting insulating substrate is used as a support substrate, semiconductor junction and electrodes are formed on the semiconductor layer surface side, and a light-receiving surface is the supporting substrate side.

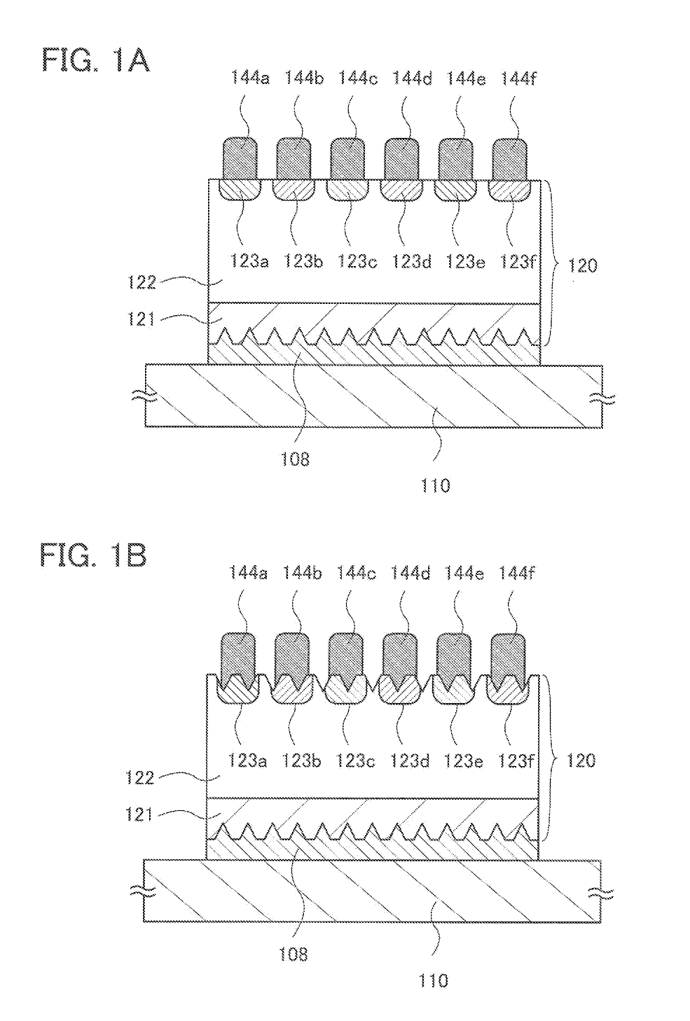

A cross-sectional view of a photoelectric conversion device in which a photoelectric conversion layer is provided over a base substrate is illustrated in FIG. 1A. There are no particular limitations on the planar shape of the photoelectric conversion layer, and a rectangular shape such as a square, a polygonal shape, or a circular shape can be employed.

There are no particular limitations on a base substrate 110 as long as the substrate can withstand a manufacturing process of the photoelectric conversion device according to one embodiment of the present invention and transmit light; for example, a light-transmitting insulating substrate can be used. Specifically, various glass substrates used in the electronics industry, such as substrates formed of aluminosilicate glass, aluminoborosilicate glass, and bariumborosilicate glass can be given, as well as a quartz substrate, a ceramic substrate, a sapphire substrate, and the like. A glass substrate, which can have a large area and is inexpensive, is preferably used because a cost reduction and productivity improvement can be achieved.

As in the cross-sectional view illustrated in FIG. 1A, a photoelectric conversion device includes a photoelectric conversion layer 120 including a single crystal semiconductor layer; the photoelectric conversion layer 120 is formed over and fixed to the base substrate 110 with an insulating layer 108 interposed therebetween. First electrodes 144a, 144c, and 144e and second electrodes 144b, 144d, and 144f are provided using conductive materials over the photoelectric conversion layer 120. Here, the electrodes are selectively formed over a plurality of impurity semiconductor layers which are formed in a stripe shape in a surface layer of the photoelectric conversion layer 120. Since the impurity semiconductor layers have high electric resistance, the electrodes are preferably formed in a stripe shape as well.

Note that the term “photoelectric conversion layer” in this specification includes in its category a semiconductor layer by which a photoelectric (internal photoelectric) effect is achieved and moreover an impurity semiconductor layer which is provided to form an internal electric field or semiconductor junction. That is to say, the photoelectric conversion layer refers to a semiconductor layer having junction typified by p-n junction, p-i-n junction, or the like.

The photoelectric conversion layer 120 includes a first single crystal semiconductor layer 121, a second single crystal semiconductor layer 122, first impurity semiconductor layers 123a, 123c, and 123e having one conductivity type, and second impurity semiconductor layers 123b, 123d, and 123f having a conductivity type which is opposite to the one conductivity type.

On a surface and its vicinity of the first single crystal semiconductor layer 121 which is in contact with the insulating layer 108, depressions are formed. The depression has a circular shape at a surface of the first single crystal semiconductor layer 121 and an internal diameter which gradually decreases. Further, as in FIG. 1B, similar depressions may be formed on a surface layer of the second single crystal semiconductor layer 122.

The number of first impurity semiconductor layers and second impurity semiconductor layers formed in the surface layer of the second single crystal semiconductor layer 122 is not limited to the number in the illustrated example. It can be increased or decreased depending on the size and crystallinity of the photoelectric conversion layer. The plurality of the impurity semiconductor layers having the same conductivity type are formed in a stripe shape across the entire surface of the photoelectric conversion layer at intervals of preferably 0.1 mm to 10 mm inclusive, more preferably, 0.5 mm to 5 mm inclusive. It is also preferable that the first impurity semiconductor layers 123a, 123c. and 123e having one conductivity type do not overlap with the second impurity semiconductor layers 123b, 123d, and 123f having a conductivity type which is opposite to the one conductivity type.

Further, the number and the shape of the first impurity semiconductor layers are the same as those of the second impurity semiconductor layers in the given example. However, in the case where the conductivity type of the second single crystal semiconductor layer 122 is either p-type or n-type, the first impurity semiconductor layers or the second impurity semiconductor layers form p-n junction. The area of the p-n junction is preferably large so that carriers induced by light may move to the p-n junction with as fewer recombinations as possible. Therefore, the numbers and the shapes of the first impurity semiconductor layers 123a, 123c, and 123e and those of the second impurity semiconductor layers 123b, 123d, and 123f are not necessarily the same. Further, even in the case where the second single crystal semiconductor layer 122 has i-type conductivity, because the life of a hole is shorter than that of an electron, carriers can be extracted with as fewer recombinations as possible if the p-i junction has a large area. Also in this case, the number and the shape of the first impurity semiconductor layers and those of the second impurity semiconductor layers are not necessarily the same, as in the case of the p-n junction.

The first single crystal semiconductor layer 121 is formed by forming a semiconductor layer including amorphous regions and a single crystal semiconductor layer over a single crystal semiconductor substrate and then etching the amorphous regions. A method for fixing the first single crystal semiconductor layer 121 to the base substrate 110 with the insulating layer 108 interposed therebetween will be described later. In this embodiment, a single crystal silicon substrate is used as the single crystal semiconductor substrate and a silicon layer including amorphous silicon regions and a single crystal silicon layer is formed. Note that a polycrystalline semiconductor substrate (typically, a polycrystalline silicon substrate) can be used instead of the single crystal semiconductor substrate. In this case, polycrystalline regions are formed in the first single crystal semiconductor layer 121.

Further, the first single crystal semiconductor layer 121 is also used as a seed for growth of the second single crystal semiconductor layer 122. Note that part of the first single crystal semiconductor layer 121 and the second single crystal semiconductor layer 122 are formed by epitaxial growth, such as solid phase epitaxy or vapor phase epitaxy, using growth of a single crystal semiconductor layer which serves as a seed.

The structure in FIG. 1B can be obtained by further forming a semiconductor layer including amorphous regions and a single crystal semiconductor layer and then etching the amorphous regions after the formation of the second single crystal semiconductor layer 122. Alternatively, although not shown, a structure is also acceptable in which the first single crystal semiconductor layer 121 does not have depressions and the second single crystal semiconductor layer 122 having depressions is formed by forming a semiconductor layer including amorphous regions and a single crystal semiconductor layer, and then etching the amorphous regions. The density of the depressions can be controlled by film formation conditions. The density of the depressions formed in an upper part of the photoelectric conversion layer 120 may be different from the density of the depressions formed in a lower part of the photoelectric conversion layer 120 in FIG. 1B. The thickness of the photoelectric conversion layer 120 including the first single crystal semiconductor layer 121 and the second single crystal semiconductor layer 122 is 1 μm to 10 μm inclusive, preferably, 2 μm to 8 μm inclusive.

Note that the conductivity type of the first single crystal semiconductor layer 121 is not limited. In this embodiment, the single crystal silicon substrate which forms the first single crystal semiconductor layer 121 and the single crystal layer over the single crystal silicon substrate are p-type. In addition, the conductivity type of the second single crystal semiconductor layer 122 is not limited; in this embodiment, the second single crystal semiconductor layer 122 formed over the first single crystal semiconductor layer 121 is p-type. Note that in the case of forming a cell using a combination of conductivity types different from the combination of conductivity types of this embodiment, a single crystal silicon substrate which has a conductivity type different from the above or a single crystal layer which has a conductivity type different from the above may be employed.

Then, n-type and p-type impurity semiconductor layers are provided in the surface layer of the second single crystal semiconductor layer 122, and semiconductor junction is formed. As an impurity element imparting n-type conductivity, phosphorus, arsenic, antimony, and the like, which belong to Group 15 in the periodic table, are typically given. As an impurity element imparting p-type conductivity, boron, aluminum, and the like, which belong to Group 13 in the periodic table, are typically given.

In this embodiment, semiconductor layers including the impurity element imparting n-type conductivity and semiconductor layers including the impurity element imparting p-type conductivity are formed in the surface layer of the second single crystal semiconductor layer 122. Here, the first impurity semiconductor layers 123a, 123e, and 123e have n-type conductivity, whereas the second impurity semiconductor layers 123b, 123d, and 123f have p-type conductivity. Therefore, the photoelectric conversion layer 120 of this embodiment has p-n junction formed between the second single crystal semiconductor layer 122 and the first impurity semiconductor layers 123a, 123c, and 123e.

Note that although the n-type and p-type impurity semiconductor layers are formed in the surface layer of the second single crystal semiconductor layer 122 by diffusing an impurity here, the impurity semiconductor layers can be formed over a surface of the second single crystal semiconductor layer 122 by film formation.

The first electrodes 144a, 144c, and 144e and the second electrodes 144b, 144d, and 144f to extract current are provided over the first impurity semiconductor layers 123a, 123c, and 123e and the second impurity semiconductor layers 123b, 123d, and 123f. These electrodes are formed using a material including metal such as nickel, aluminum, silver, or solder. Specifically, these electrodes can be formed using a nickel paste, a silver paste, or the like by a screen printing method.

Further, a modular structure which can provide desired voltage and current may be formed when a plurality of photoelectric conversion layers are provided over the base substrate 110 and a first connection electrode, which is connected to the first electrodes over one of the photoelectric conversion layers and to the second electrodes over an adjacent photoelectric conversion layer, and a second connection electrode, which is connected to the second electrodes over the one of the photoelectric conversion layers and to the first electrodes over another adjacent photoelectric conversion layers, are formed.

Light which passes through the light-transmitting base substrate 110 generates carriers in the first single crystal semiconductor layer 121 and the second single crystal semiconductor layer 122, which is a substantial light absorption layer. The generated carriers can be diffused to a region which is influenced by an internal electric field formed by the second single crystal semiconductor layer 122 and the first impurity semiconductor layers 123a, 123c, and 123e. The carriers then move to the first electrodes 144a, 144c, and 144e and the second electrodes 144b, 144d, and 144f and are extracted as current. Only the insulating layer 108 having a light-transmitting property is interposed between the light-transmitting base substrate 110 and the first single crystal semiconductor layer 121; therefore, a highly efficient photoelectric conversion device without loss due to the shadow of a collection electrode can be manufactured.

The depressions of the first single crystal semiconductor layer 121 on a light incident side not only increase the area of the light-receiving surface but provide a light-trapping effect so that light is scattered in the semiconductor layer. Accordingly, in the photoelectric conversion device provided with depressions, more photo-carriers can be generated. In addition, by providing depressions on the surface layer of the second single crystal semiconductor layer 122, a light-trapping effect can be further enhanced.

As described above, a photoelectric conversion device according to this embodiment can save resources while it uses a highly efficient single crystal semiconductor layer as a photoelectric conversion layer. Further, since the photoelectric conversion device according to this embodiment has a back contact structure, a collection electrode on the light-receiving surface is unnecessary and a shadow loss is eliminated, whereby the photoelectric conversion efficiency can be increased. In addition, since the light-receiving surface is on the light-transmitting base substrate side, a highly efficient integration process can be employed as in the case of a thin film photoelectric conversion device, and a module can have a superstrate structure with high mechanical strength.

Then, a manufacturing method of the photoelectric conversion device (see FIG. 1A) in this embodiment will be described with reference to drawings.

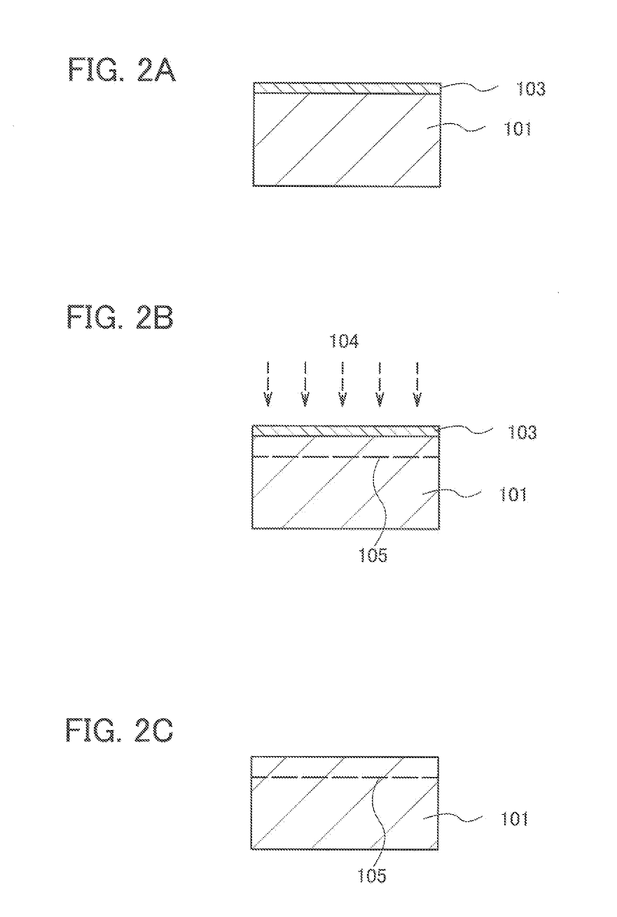

A single crystal semiconductor substrate 101 is prepared and an insulating layer 103, for example, a thermal oxide film is formed (see FIG. 2A).

As the single crystal semiconductor substrate 101, a single crystal silicon substrate is typically employed. Alternatively, a known single crystal semiconductor substrate can be used; for example, a single crystal germanium substrate, a single crystal silicon-germanium substrate, or the like can be used. As an alternative to the single crystal semiconductor substrate 101, a polycrystalline semiconductor substrate can be used; typically, a polycrystalline silicon substrate can be used. Therefore, in the case of using a polycrystalline semiconductor substrate instead of the single crystal semiconductor substrate, the “single crystal semiconductor” in the description below can be replaced with a “polycrystalline semiconductor.”

The single crystal semiconductor substrate 101 can be an n-type or p-type single crystal semiconductor substrate. For example, the concentration of an impurity imparting p-type conductivity in a p-type single crystal semiconductor substrate is approximately 1×10¹⁴ atoms/cm³ to 1×10¹⁷ atoms/cm³, and the resistivity is approximately 1×10⁻¹ Ω·cm to 10 Ω·cm. In addition, a single crystal semiconductor substrate with a {100} surface orientation which facilitates epitaxial growth is preferably used. In this embodiment, a p-type single crystal semiconductor substrate is used as the single crystal semiconductor substrate 101.

The size (the area, the planar shape, the thickness, or the like) of the single crystal semiconductor substrate 101 may be determined by a practitioner with respect to the specifics of a manufacturing apparatus or the specifics of the photoelectric conversion device. For example, as for the planar shape of the single crystal semiconductor substrate 101, a widely distributed circular substrate or a substrate processed into a desired shape can be used.

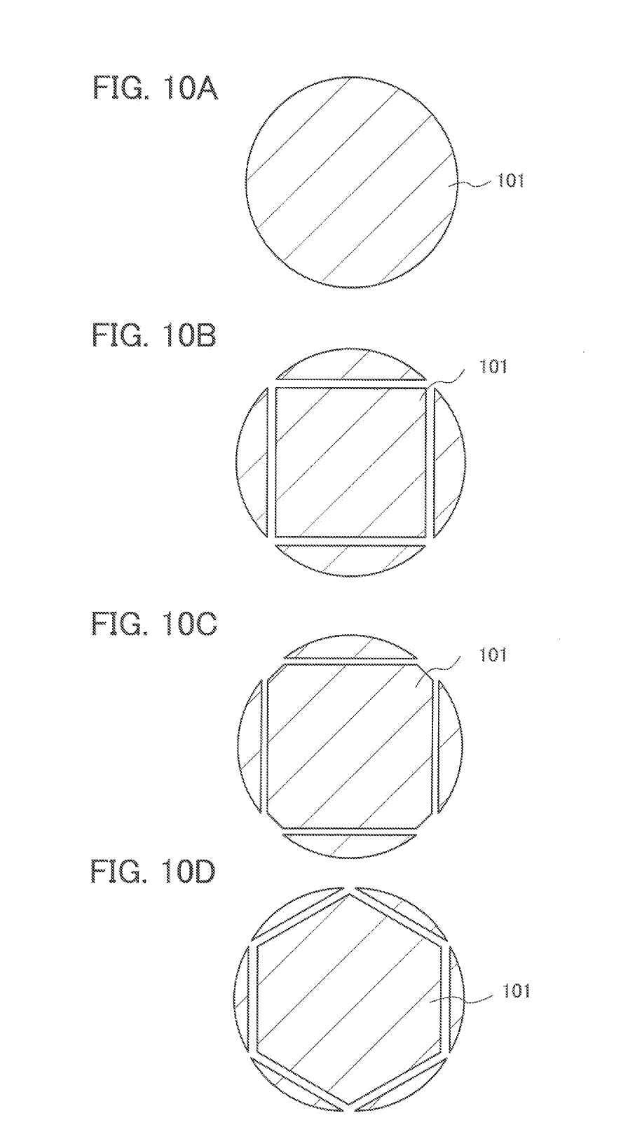

An example of the single crystal semiconductor substrate 101 will now be described. For example, the single crystal semiconductor substrate 101 illustrated in FIGS. 10A, 10B, 10C, and 10D can be used.

A circular single crystal semiconductor substrate 101 may be used without being cut as illustrated in FIG. 10A. Alternatively, a substantially rectangular single crystal semiconductor substrates 101 may be cut out from the circular substrate to be used as illustrated in FIGS. 10B and 10C.

FIG. 10B illustrates an example in which the rectangular single crystal semiconductor substrate 101 is cut out to have a rectangular shape of maximum size inscribed in the circular single crystal semiconductor substrate 101. The angle at each corner of the single crystal semiconductor substrate 101 is approximately 90°.

FIG. 10C illustrates an example in which the single crystal semiconductor substrate 101 is cut out so that the distance between opposite lines is longer than that illustrated in FIG. 10B. The angle at each corner of the single crystal semiconductor substrate 101 is not 90°, and the single crystal semiconductor substrate 101 has a polygonal shape, not a rectangular shape.

Further alternatively, as illustrated in FIG. 10D, a hexagonal single crystal semiconductor substrate 101 may be cut out. FIG. 10D illustrates an example in which the hexagonal single crystal semiconductor substrate 101 is cut out to have a hexagonal shape of maximum size inscribed in the circular single crystal semiconductor substrate 101. When a hexagonal single crystal semiconductor substrate is cut out, the cutting edge of the substrate can be reduced compared to the case of cutting out a rectangular single crystal semiconductor substrate.

Here is described the example in which a substrate with a desired shape is cut out from a circular single crystal semiconductor substrate. However, one embodiment of the present invention is not limited thereto, and a substrate with a desired shape may be cut out from a substrate with a shape other than a circular shape. A single crystal semiconductor substrate which is processed into a desired shape is easily used in a manufacturing apparatus which is used for the manufacture process of the photoelectric conversion device. In addition, when the photoelectric conversion module is formed, the photoelectric conversion layers can be easily connected to each other.

The single crystal semiconductor substrate 101 may have a thickness of a generally distributed substrate which conforms to the SEMI Standard, or may have a thickness which is adjusted as appropriate at the time of cutting out the single crystal semiconductor substrate 101 from an ingot. It is preferable that a thick single crystal semiconductor substrate be cut out from an ingot, because a useless cutting margin can be reduced.

The single crystal semiconductor substrate 101 may have a large area. As for single crystal silicon substrates, substrates with a diameter of approximately 100 mm (4 inches), a diameter of approximately 150 mm (6 inches), a diameter of approximately 200 mm (8 inches), a diameter of approximately 300 mm (12 inches), and the like are widely distributed, and a large substrate with a diameter of approximately 400 mm (16 inches) has started to be distributed in recent years. Further, it has already been expected that a substrate is increased to approximately 450 mm (18 inches) in diameter so as to be used as a next-generation substrate. When the single crystal semiconductor substrate 101 with a large area is used, a plurality of photoelectric conversion layers can be formed with one substrate, and an area of spaces (non-electricity generation regions) which are generated by arrangement of a plurality of photoelectric conversion layers can be reduced, which can lead to improvement in productivity.

An embrittlement layer 105 is formed in a region at a predetermined depth from one surface of the single crystal semiconductor substrate 101 (see FIG. 2B).

The embrittlement layer 105 refers to a boundary and its vicinity in which the single crystal semiconductor substrate 101 is divided into a single crystal semiconductor layer and a separation substrate (a single crystal semiconductor substrate which has been separated from the single crystal semiconductor layer which is bonded to the insulating layer) by a division step which is described later. The depth at which the embrittlement layer 105 is formed is determined based on the thickness of the single crystal semiconductor layer which is formed later by the division.

As a method for forming the embrittlement layer 105, an ion implantation method or an ion doping method, in each of which irradiation with ions accelerated by voltage is performed, a method utilizing multiphoton absorption, or the like can be used.

For example, the embrittlement layer 105 can be formed by introduction of hydrogen, helium and/or a halogen into the single crystal semiconductor substrate 101. In one example illustrated in FIG. 2B, one surface of the single crystal semiconductor substrate 101 is irradiated with ions 104 which are accelerated by voltage to form the embrittlement layer 105 in a region at a predetermined depth of the single crystal semiconductor substrate 101. Specifically, the single crystal semiconductor substrate 101 is irradiated with ions (typically, hydrogen ions) which are accelerated by voltage so that the ions or elements of the ions (hydrogen in the case of hydrogen ions) are introduced into the single crystal semiconductor substrate 101, which leads to local distortion of the crystal structure of the single crystal semiconductor substrate 101 and embrittlement and thus the embrittlement layer 105 is formed.

In this specification, “ion implantation” refers to a method in which ions produced from a source gas are mass-separated and delivered to an object, so that elements of the ions are added to the object. Further, “ion doping” refers to a method in which ions produced from a source gas are delivered to an object without mass separation, so that elements of the ions are added to the object. The embrittlement layer 105 can be formed using either an ion implantation apparatus with mass separation or an ion doping apparatus without mass separation.

The depth at which the embrittlement layer 105 is formed in the single crystal semiconductor substrate 101 (here, the depth from the irradiated surface of the single crystal semiconductor substrate 101 to the embrittlement layer 105 in the film thickness direction) can be controlled by, for example, acceleration voltage of ions for irradiation and/or a tilt angle (an inclination angle of the substrate). Therefore, in consideration of the desired thickness of the single crystal semiconductor layer after the division, the acceleration voltage of ions and/or the tilt angle is determined.

As the irradiation ions, hydrogen ions generated from a source gas including hydrogen is preferable. When the single crystal semiconductor substrate 101 is irradiated with hydrogen ions, hydrogen is introduced thereto, so that the embrittlement layer 105 is formed in a region at a predetermined depth of the single crystal semiconductor substrate 101. For example, hydrogen plasma is generated from a source gas including hydrogen and the ions generated in the hydrogen plasma are accelerated by voltage and delivered; thus, the embrittlement layer 105 can be formed. Instead of hydrogen or in addition to hydrogen, ions generated from a source gas including a rare gas typified by helium or a halogen may be used to form the embrittlement layer 105. Note that the irradiation with particular ions is preferable because the region at a given depth in the single crystal semiconductor substrate 101 is weakened in a concentrated manner.

For example, the single crystal semiconductor substrate 101 is irradiated with ions generated from hydrogen, so that the embrittlement layer 105 is formed. By adjusting the acceleration voltage, the tilt angle, and the dosage of the irradiation ions, the embrittlement layer 105, which is the region doped with hydrogen at high concentration, can be formed at a predetermined depth of the single crystal semiconductor substrate 101. In the case of using ions generated from hydrogen, the region which becomes the embrittlement layer 105 preferably includes hydrogen atoms at the peak value of 1×10¹⁹ atoms/cm³ or more. The embrittlement layer 105, which is the region locally doped with hydrogen at high concentration, no longer has a crystalline structure but has a porous structure including microvoids. When heat treatment is performed at relatively low temperatures (approximately 700° C. or lower), the volume of the microvoids in the embrittlement layer 105 change in volume, so that the single crystal semiconductor substrate 101 can be divided at or in the vicinity of the embrittlement layer 105.

Note that a protective layer is preferably formed on a surface of the single crystal semiconductor substrate 101 which is irradiated with the ions, in order to prevent damage to the surface portion of the single crystal semiconductor substrate 101. In the example illustrated in FIGS. 2A and 2B, the insulating layer 103 is formed as a protective layer on at least one surface of the single crystal semiconductor substrate 101 and the surface of the substrate where the insulating layer is formed is irradiated with the ions accelerated by voltage. The insulating layer 103 is irradiated with the ions and the ions or elements of the ions that transmit through the insulating layer 103 are introduced to the single crystal semiconductor substrate 101. Thus, the embrittlement layer 105 is formed in a region at a predetermined depth of the single crystal semiconductor substrate 101.

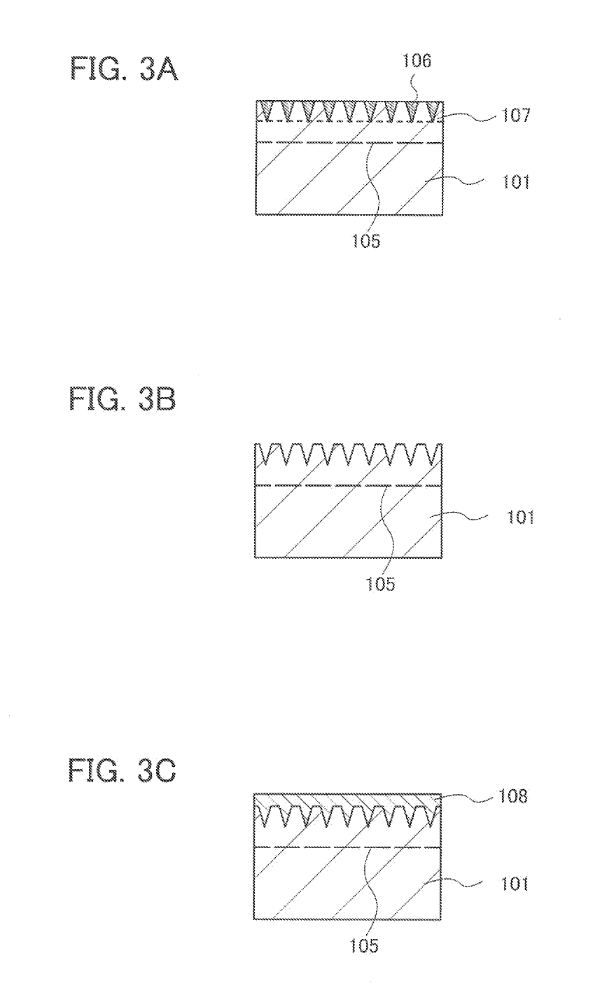

Then, the insulating layer 103, which serves as a protective layer, is removed (see FIG. 2C). Then, a semiconductor layer including amorphous regions 106 and a single crystal semiconductor layer 107 is formed on the single crystal semiconductor substrate (see FIG. 3A).

The conditions of a plasma CVD method for vapor phase growth of the semiconductor layer including the amorphous regions 106 and the single crystal semiconductor layer 107 on the single crystal semiconductor substrate 101 vary depending on a flow ratio of reaction gasses, a temperature at which the substrate is heated, and the like.

In this embodiment, a plasma CVD apparatus for vapor phase growth of the semiconductor layer including the amorphous regions 106 and the single crystal semiconductor layer 107 is a parallel plate plasma CVD apparatus which uses a high frequency power of 27 MHz, and in which an area of an electrode is 300 cm² and the distance between electrodes is 25 mm. Note that these conditions of the CVD apparatus are not necessarily strictly adhered to. By employing following conditions, the desired layer can be formed.

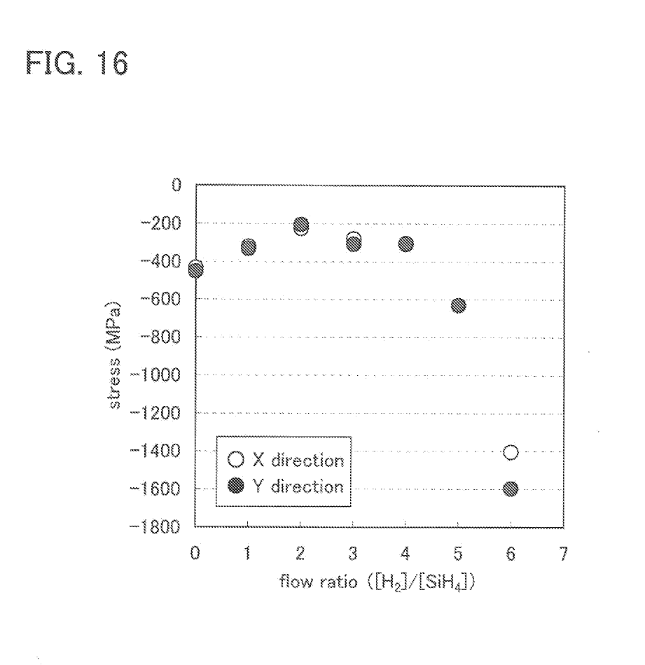

FIG. 16 shows the measurement result of stress of silicon films which are formed on a silicon wafer with different flow ratios of source gases (silane and hydrogen). Note that film formation conditions other than the flow ratio of the gasses are as follows: the substrate temperature is 280° C., the film formation pressure is 66.6 Pa, and the RF power density is 0.3 W/cm². As can be seen from FIG. 16, a silicon film with a small stress can be formed when the flow rate of a dilution gas (hydrogen) is equal to or less than five times that of the semiconductor source gas (silane), preferably, equal to or greater than one time and equal to or less than four times that of the semiconductor source gas (silane). If the dilution rate is not within this range, a high compressive stress is applied to the formed film, which may result in peeling off of the film from the single crystal semiconductor substrate.

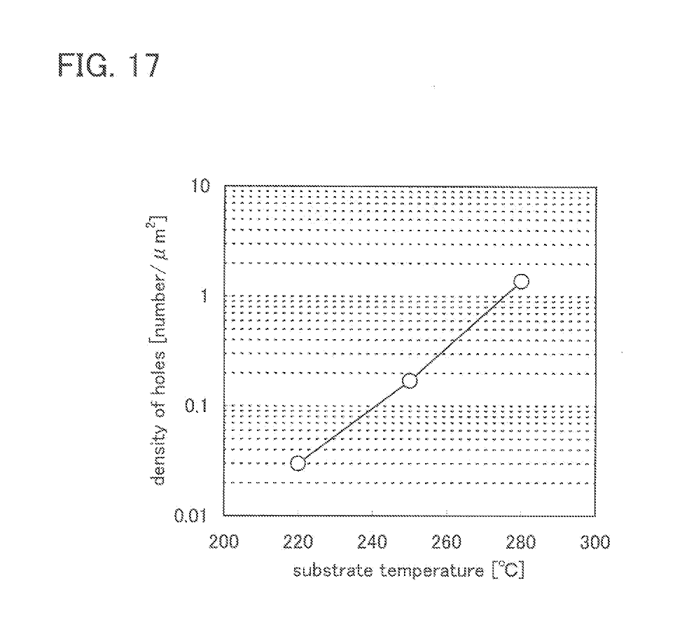

FIG. 17 shows the relationship between the density of holes, which are formed by etching amorphous regions in a semiconductor layer including the amorphous regions and a single crystal semiconductor layer, and a film formation temperature. In order to form amorphous regions in a single crystal layer, a substrate temperature is preferably within the range of 220° C. to 280° C. inclusive, more preferably, within the range of 250° C. to 280° C. in the case where a flow ratio of a dilution gas (hydrogen) to a semiconductor source gas (silane) is 1:4, a film formation pressure is 66.6 Pa, and a RF power density is 0.3 W/cm². As is apparent from FIG. 17, the density of the amorphous regions 106 increases as the film formation temperature increases. Outside the above temperature range, the density of the amorphous regions 106 increases and thus a later planarization step becomes difficult or epitaxial growth is not caused in some cases.

In addition, in the case where the flow ratio of the dilution gas (hydrogen) to the semiconductor source gas (silane) is 1:4, the film formation pressure is 66.6 Pa, and the film formation temperature is 280° C.; a RF power density is preferably within the range of 0.1 W/cm² to 0.3 W/cm² inclusive, more preferably within the range of 0.2 W/cm² to 0.3 W/cm² inclusive. Outside the above power density range, the density of the amorphous regions 106 increases and thus a later planarization step becomes difficult or epitaxial growth is not caused in some cases.

Further, if a doping gas is mixed into the reaction gas, an n-type or p-type single crystal semiconductor layer can be formed by epitaxial growth. For example, in order to form an n-type single crystal semiconductor layer by vapor phase growth, a compound gas including a Group 15 element in the periodic table, typically phosphine (PH₃) or arsine (AsH₃), may be used. In order to form a p-type single crystal semiconductor layer by epitaxial growth, a compound gas including a Group 13 element in the periodic table, typically diborane (B₂H₆), may be used.

Then, the formed semiconductor layer including the amorphous regions 106 and the single crystal semiconductor layer 107 undergoes selective etching of the amorphous regions 106. Here, high etching selectivity between the amorphous regions 106 and the single crystal semiconductor layer 107 is preferable. For example, by using an acid including a hydrofluoric acid such as Dash, Sirtle, Secco, Wright, or Sato etchant, the amorphous regions 106 can selectively be etched. A chromium-free Dash or Sato etchant is preferably used as an oxidizing agent in consideration of environment.

After the amorphous regions 106 are removed from the semiconductor layer including the amorphous regions 106 and the single crystal semiconductor layer 107 as described above, the resulting structure forms a continuous structure with the single crystal semiconductor substrate 101 provided with the embrittlement layer 105. An upper portion of the structure has depressions as illustrated in FIG. 3B. Since the single crystal semiconductor substrate 101 and the single crystal semiconductor layer 107 forms a continuous structure, they are collectively referred to as the single crystal semiconductor substrate 101 hereinafter in this embodiment.

Then, the insulating layer 108 is formed so as to fill the depressions in the upper portion of the single crystal semiconductor substrate 101 and the surface of the insulating layer 108 is planarized (see FIG. 3C).

The insulating layer 108 can have a single-layer structure or a stacked structure including two or more layers of different materials. The surface (a bonding plane) to be bonded to the base substrate 110 later and form a bonding preferably has good planarity, and more preferably has hydrophilicity. Specifically, when the insulating layer 108 is formed so that the average surface roughness (Ra) of the bonding plane is 0.5 nm or less, preferably, 0.3 nm or less, the attachment with the base substrate 110 can be performed favorably. Apparently, the average surface roughness (Ra) is preferably small. Note that the average surface roughness (Ra) in this specification refers to centerline average roughness obtained by three-dimensional expansion of the centerline average roughness which is defined by JIS B0601 so as to apply to a plane.

For example, as a layer that forms the bonding plane of the insulating layer 108, a silicon oxide layer, a silicon nitride layer, a silicon oxynitride layer, a silicon nitride oxide layer, or the like is formed by a CVD method such as a plasma CVD method, a photo CVD method, or a thermal CVD method (including a low-pressure CVD method and an atmospheric pressure CVD method). The insulating layer 108 is preferably formed by a plasma CVD method in order to form a layer with good planarity. Further, in order to facilitate filling of the depressions formed in the upper portion of the single crystal semiconductor substrate 101, a film formation method for the insulating layer may be any one or a combination of liquid phase methods such as a SOG method, spin coating, dipping, spray coating, or a droplet discharge method.

As a specific material for forming a film with hydrophilicity and good planarity, thermally oxidized silicon, silicon oxide a film of which is formed by a plasma CVD method using an organosilane gas, or the like is given. By using these materials, the bonding with the substrate can be strengthened. As an organosilane gas, a silicon-containing compound such as tetraethoxysilane (TEOS), tetramethylsilane (TMS), tetramethylcyclotetrasiloxane (TMCTS), octamethylcyclotetrasiloxane (OMCTS), hexamethyldisilazane (HMDS), triethoxysilane (TRIES), or tris(dimethylamino)silane (TDMAS) can be used.

In addition, as a material which can form a film with hydrophilicity and good planarity, a silicon oxide, silicon oxynitride, silicon nitride, or silicon nitride oxide a film of which is formed by a plasma CVD method using a silane-based gas such as silane, disilane, or trisilane can be used. For example, as the layer that forms the bonding plane of the insulating layer 108, a silicon nitride layer formed by a plasma CVD method using silane and ammonia as a source gas can be used. Note that hydrogen may be added to the source gas including silane and ammonia; alternatively, nitrous oxide may be added to the source gas so that a silicon nitride oxide layer is formed. When at least one layer included in the insulating layer 108 is a silicon insulating layer including nitrogen, specifically a silicon nitride layer or a silicon nitride oxide layer, diffusion of impurities from the base substrate 110 which is attached to the insulating layer 108 later can be prevented.

Note that a silicon oxynitride layer means a layer that includes more oxygen than nitrogen and specifically includes oxygen, nitrogen, silicon, and hydrogen at concentrations ranging from 50 at. % to 70 at. %, 0.5 at. % to 15 at. %, 25 at. % to 35 at. %, and 0.1 at. % to 10 at. %, respectively in the case where measurements are performed using Rutherford backscattering spectrometry (RBS) and hydrogen forward scattering (HFS). Further, a silicon nitride oxide layer means a layer that includes more nitrogen than oxygen and specifically includes oxygen, nitrogen, silicon, and hydrogen at concentrations ranging from 5 at. % to 30 at. %, 20 at. % to 55 at. %, 25 at. % to 35 at. %, and 10 at. % to 30 at. %, respectively in the case where measurements are performed using RBS and HFS. Note that percentages of nitrogen, oxygen, silicon, and hydrogen fall within the ranges given above, where the total of atoms contained in the silicon oxynitride film or the silicon nitride oxide film is defined as 100 at. %.

In any case, the insulating layer 108 is not limited to an insulating layer including silicon, as long as the insulating layer 108 has a planar bonding plane, specifically, the insulating layer 108 has a planar bonding plane with an average surface roughness (Ra) of 0.5 nm or less, preferably, 0.3 nm or less. Note that in the case where the insulating layer 108 has a stacked structure, the layers other than the layer which forms the bonding plane are not limited thereto. In this embodiment, the insulating layer 108 needs to be formed at a temperature at which the embrittlement layer 105 formed in the single crystal semiconductor substrate 101 does not change, preferably at 350° C. or lower.

Then, a surface of the insulating layer 108, which is one surface of the single crystal semiconductor substrate 101, and a surface of the base substrate 110 are made to face each other, and superposed and attached.

Here, the base substrate 110 and the single crystal semiconductor substrate 101, which are superimposed, are pressed at one place, whereby van der Waals forces or hydrogen bond can be spread over the entire area of the bonding planes. When one or both of the bonding planes have hydrophilic surfaces, hydroxyl groups or water molecules serve as an adhesive and water molecules diffuse in later heat treatment; then, the remaining composition forms silanol groups (Si—OH) and the bonding is formed by hydrogen bonding. Further, this bonding portion forms a siloxane bonding (O—Si—O) by release of hydrogen to have a covalent bond, whereby the bond can be further strengthened.

The bonding plane of the single crystal semiconductor substrate 101 and the bonding plane of the base substrate 110 each preferably have an average surface roughness (Ra) of 0.5 nm or less, more preferably, 0.3 nm or less. Further, the sum of the average surface roughness (Ra) of the bonding plane of the single crystal semiconductor substrate 101 and the bonding plane of the base substrate 110 is 0.7 nm or less, preferably 0.6 nm or less, more preferably 0.4 nm or less. The bonding plane of the single crystal semiconductor substrate 101 and the bonding plane of the base substrate 110 each have a contact angle to pure water of 20° or less, preferably 10° or less, more preferably 5° or less. The sum of contact angle to pure water of the bonding plane of the single crystal semiconductor substrate 101 and the bonding plane of the base substrate 110 is 30° or less, preferably, 20° or less, more preferably, 10° or less. If the bonding planes are attached under the above conditions, they can be attached favorably, whereby the bond can be strengthened.

Note that before the single crystal semiconductor substrate 101 and the base substrate 110 are attached to each other, the single crystal semiconductor substrate 101 or the insulating layer 108 over the single crystal semiconductor substrate 101, or the base substrate 110 or an insulating layer over the base substrate 110 preferably undergoes surface treatment. The surface treatment can increase the bond strength at the interface between the single crystal semiconductor substrate 101 and the base substrate 110.

As examples of the surface treatment, wet treatment, dry treatment, and a combination of wet treatment and dry treatment can be given. Alternatively, a combination of different kinds of wet treatment or a combination of different kinds of dry treatments can be employed.

As examples of the wet treatment, ozone treatment using ozone water (ozone water cleaning), megasonic cleaning, two-fluid cleaning (method in which functional water such as pure water or hydrogenated water and a carrier gas such as nitrogen are sprayed together), and the like can be given. As examples of the dry treatment, ultraviolet treatment, ozone treatment, plasma treatment, plasma treatment with bias application, radical treatment, and the like can be given. Such surface treatment has an effect of improving the hydrophilicity and cleanliness of the surface of the object. As a result, the bond strength between the substrates can be improved.

The wet treatment is effective for removal of macro dust and the like attached to the surface of the object; the dry treatment is effective for removal or decomposition of micro dust and the like such as an organic substance attached to the surface of the object. That is, when the dry treatment such as ultraviolet treatment is performed on the object and then the wet treatment such as cleaning is performed on the object, cleanliness and hydrophilicity of the surface of the object can be promoted. Further, generation of watermarks on the surface of the object can be suppressed.

As the dry treatment, it is preferable to perform surface treatment using ozone or oxygen in an active state such as singlet oxygen. Ozone or oxygen in an active state such as singlet oxygen enables organic substances attached to the surface of the object to be removed or decomposed effectively. Further, when surface treatment using ozone or oxygen in an active state such as singlet oxygen and using light having a wavelength less than 200 nm is performed, the organic substances attached to the surface of the object can be removed more effectively. Specific description thereof will be made below.

For example, the surface treatment of the object is performed by irradiation with ultraviolet light in an atmosphere containing oxygen. By irradiation with light having a wavelength less than 200 nm and light having a wavelength of 200 nm or more in an atmosphere containing oxygen, singlet oxygen as well as ozone can be generated. In addition, by irradiation with light having a wavelength less than 180 nm, singlet oxygen as well as ozone can be generated.

An example of a reaction caused by the irradiation with light having a wavelength less than 200 nm and light having a wavelength of 200 nm or more in an atmosphere containing oxygen is described.

O₂+hν(λ₁ nm)→O(³P)+O(³P) (1)

O(³P)+O₂→O₃ (2)

O₃+hν(λ₂ nm)→O(¹D)+O₂ (3)

First, irradiation with light (hν) having a wavelength (λ₁ nm) less than 200 nm in an atmosphere including oxygen (O₂) is performed to generate an oxygen atom (O(³P)) in a ground state (reaction formula (1)). Next, an oxygen atom (O(³P)) in the ground state and oxygen (O₂) are reacted with each other to generate ozone (O₃) (reaction formula (2)). Then, by irradiation with light having a wavelength (λ₂ nm) of 200 nm or more in an atmosphere including the generated ozone (O₃), singlet oxygen O(¹D) in an excited state is generated (reaction formula (3)). In an atmosphere including oxygen, irradiation with light having a wavelength less than 200 nm is performed to generate ozone and irradiation with light having a wavelength of 200 nm or more is performed to generate singlet oxygen by decomposing ozone. The above surface treatment can be performed by, for example, irradiation with a low-pressure mercury lamp (λ₁=185 nm, λ₂=254 nm) in the atmosphere including oxygen.

Further, an example of a reaction caused by the irradiation with light having a wavelength less than 180 nm in an atmosphere containing oxygen is described.

O₂+hν(λ₃ nm)→O(¹D)+O(³P) (4)

O(³P)+O₂→O₃ (5)

O₃+hν(λ₃ nm)→O(¹D)+O₂ (6)

First, by irradiation with light having a wavelength less than 180 nm (λ₃ nm) in an atmosphere containing oxygen (O₂), singlet oxygen in an excited state O(¹D) and an oxygen atom in the ground state (O(³P)) are generated (reaction formula (4)). Next, the oxygen atoms (O(³P)) in the ground state and the oxygen (O₂) are reacted to generate ozone (O₃) (reaction formula (5)). Then, by irradiation with light having a wavelength less than 180 nm (λ₃ nm) in an atmosphere containing the generated ozone (O₃), singlet oxygen in an excited state and oxygen are generated (reaction formula (6)). In an atmosphere including oxygen, the irradiation with light having a wavelength less than 180 nm, which is an ultraviolet ray, is performed to generate ozone as well as to decompose ozone or oxygen and to generate singlet oxygen. The above surface treatment can be performed with, for example, irradiation with a Xe excimer UV lamp in the atmosphere including oxygen.

The light having a wavelength less than 200 nm causes breakage of a chemical bond in an organic substance and the like attaching to the surface of the object and the organic substance can be oxidative-decomposed by ozone or singlet oxygen and removed. The above surface treatment can enhance the hydrophilicity and cleanliness of the surface of the object, making the bond more preferable.

Note that the bonding planes may be attached after the bonding planes are irradiated with an atomic beam or an ion beam or the bonding planes are subjected to plasma treatment or radical treatment. With such a treatment, the bonding planes can be activated so that the attachment can be performed favorably. For example, the bonding planes can be activated by irradiation with an inert gas neutral atomic beam of argon or an inert gas ion beam of argon or the like or activated by being exposed to oxygen plasma, nitrogen plasma, oxygen radicals, or nitrogen radicals. By activation of the bonding planes, they can be bonded at low temperatures (e.g., 400° C. or lower) even when the substrates including different materials as main components are to be bonded to each other, for example, an insulating layer and a glass substrate. Further, when the bonding planes are processed with oxygen-added water, hydrogen-added water, pure water, or the like, the bonding plane are made hydrophilic and the number of hydroxyls on the bonding planes is increased, whereby a strong bond can be formed

Although an example in which one single crystal semiconductor substrate 101 is disposed with respect to one base substrate 110 has been described in this embodiment, a plurality of single crystal semiconductor substrates may be disposed with respect to one base substrate. The single crystal semiconductor substrates may be arranged over the base substrate one by one, but a plurality of single crystal semiconductor substrates can be arranged at one time when a holding means such as a tray is used, for example. More preferably, a desired number of single crystal semiconductor substrates are held by the holding means and arranged at one time so as to be arranged over the base substrate at predetermined intervals. It is preferable that the shape or the like of the holding means be determined accordingly sot that the single crystal semiconductor substrate and the base substrate may be easily aligned. Needless to say, the single crystal semiconductor substrates may be aligned to be disposed over the base substrate one by one. The holding means of the single crystal semiconductor substrates may be a tray, a substrate for holding, a vacuum chuck, or an electrostatic chuck.

After the single crystal semiconductor substrates 101 and the base substrate 110 are superposed on each other, heat treatment and/or pressure treatment is preferably performed. Heat treatment and/or pressure treatment can increase the bond strength. When the heat treatment is performed, the temperature of the heat treatment is set at a temperature at which is lower than or equal to the strain point of the base substrate 110 and at which the volume of the embrittlement layer 105 formed in the single crystal semiconductor substrate 101 does not change. The temperature is preferably 200° C. or more and lower than 410° C. The step in which the single crystal semiconductor substrate 101 and the base substrate 110 are superposed on each other and the heat treatment are preferably performed in succession. In the case of performing the pressure treatment, pressure is perpendicularly applied to the bonding planes in consideration of the pressure resistance of the base substrate 110 and the single crystal semiconductor substrate 101. The heat treatment for increasing the bond strength and heat treatment for dividing the single crystal semiconductor substrates 101 at the embrittlement layer 105 which is described later may be performed in succession.

Alternatively, an insulating layer such as a silicon oxide layer, a silicon nitride layer, a silicon oxynitride layer, or a silicon nitride oxide layer may be formed over the base substrate 110, and the base substrate 110 may be attached to the single crystal semiconductor substrate 101 with the insulating layer interposed therebetween. For example, the insulating layer formed over the base substrate 110 and the insulating layer formed over the single crystal semiconductor substrate 101 can serve as the bonding planes which are bonded to each other.

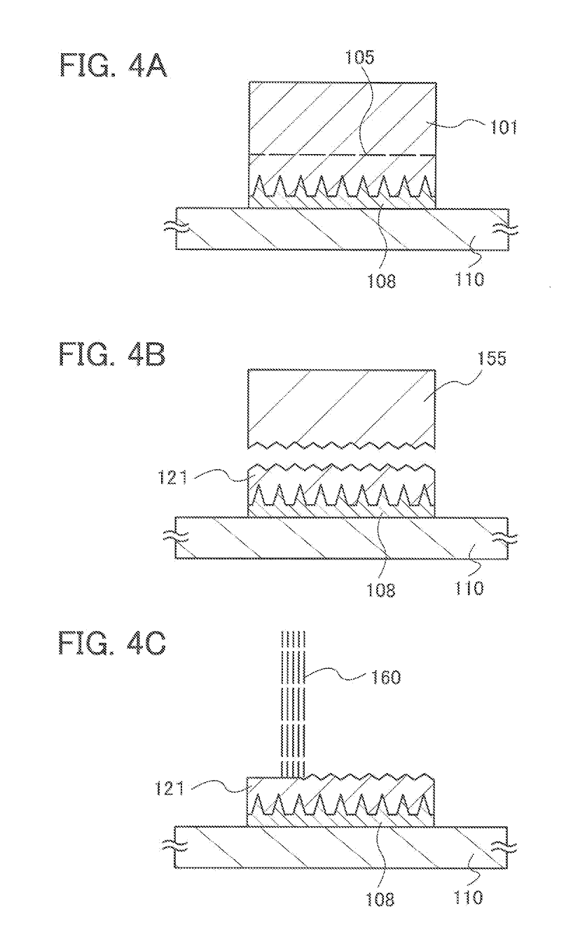

Next, the single crystal semiconductor substrate 101 is divided at the embrittlement layer 105; thus, the first single crystal semiconductor layer 121 is provided over the base substrate 110 (see FIG. 4B).

As in this embodiment, it is preferable to use heat treatment for dividing the single crystal semiconductor substrate at the embrittlement layer 105. The heat treatment can be performed with a rapid thermal annealing (RTA) apparatus, a furnace, a heat treatment apparatus for dielectric heating which uses a high frequency wave such as a microwave or millimeter wave generated by a high-frequency generator. As a heating method of the heat treatment apparatus, a resistance heating method, a lamp heating method, a gas heating method, an electromagnetic heating method, and the like can be given. Alternatively, laser beam irradiation or thermal plasma jet irradiation may be performed. An RTA apparatus can heat an object rapidly, and can heat the single crystal semiconductor substrate 101 up to a temperature approximately equal to or slightly higher than the strain point of the single crystal semiconductor substrate 101 (or the base substrate 110). The suitable temperature in the heat treatment for dividing the single crystal semiconductor substrate 101 is 410° C. or higher and lower than the strain point of the single crystal semiconductor substrate 101 (and lower than the strain point of the base substrate 110). By the heat treatment performed at 410° C. or higher, volume of the microvoids formed in the embrittlement layer 105 change so that the single crystal semiconductor substrate 101 can be divided at or in the vicinity of the embrittlement layer 105.

For example, the thickness of the first single crystal semiconductor layer 121 layer separated from the single crystal semiconductor substrate 101 can be 20 nm to 1000 nm inclusive, preferably 40 nm to 300 nm inclusive. Needless to say, a single crystal semiconductor layer having a thickness equal to or larger than the above thickness can be separated from the single crystal semiconductor substrate 101 by adjusting the acceleration voltage in forming the embrittlement layer.

The single crystal semiconductor substrate 101 is separated at the embrittlement layer 105, whereby the single crystal semiconductor layer which has been a part of the single crystal semiconductor substrate is separated and the first single crystal semiconductor layer 121 is formed. Thus, a separation substrate 155, that is, the single crystal semiconductor substrate 101 from which the single crystal semiconductor layer which has been a part thereof is separated, is obtained. The separation substrate 155 can be reused repeatedly after being reprocessed. The separation substrate 155 may be used as a single crystal semiconductor substrate for forming a photoelectric conversion device, or may be used for other purposes. By repeatedly using the separation substrate 155 as the single crystal semiconductor substrate which is used for one embodiment of the present invention, it is possible to manufacture a plurality of photoelectric conversion devices out of one substrate.

Due to the division of the single crystal semiconductor substrate 101 at the embrittlement layer 105, the division plane (the separation plane) of the separated single crystal semiconductor layer (here, the first single crystal semiconductor layer 121) becomes rough in some cases. Crystallinity and planarity of such a rough surface are lost due to ion damage, and it is preferable that crystallinity and planarity of a surface be recovered so that the single crystal semiconductor layer may serve as a seed layer when epitaxial growth is performed later. In order to recover crystallinity and remove a damaged layer, laser treatment or an etching process can be used, and planarity can be recovered at the same time.

Next, an example in which recovery of crystallinity and planarization can be performed by laser treatment will be described. For example, as illustrated in FIG. 4C, a laser beam 160 can be delivered to an upper surface of the first single crystal semiconductor layer 121 provided over the base substrate 110 and the single crystal semiconductor layer is melted and solidified, whereby crystallinity and planarity of the first single crystal semiconductor layer 121 can be recovered.

Although the melting state of the single crystal semiconductor layer formed by irradiation with the laser beam 160 may be either partly-melted state or completely-melted state, the partly-melted state which is formed in such a way that only the upper layer (on the surface layer side) is melted to be a liquid phase is preferable. In the partly-melted state, crystal growth can be carried out using the solid phase portion of a single crystal as a seed. Note that in this specification, the completely-melted state refers to a state in which the single crystal semiconductor layer is melted down to the vicinity of the lower interface of the single crystal semiconductor layer to be in a liquid phase. The partly-melted state refers to a state in which part (e.g., an upper portion) of the single crystal semiconductor layer is melted to be in a liquid phase whereas the other part (e.g., a lower portion) is kept in a solid phase without being melted.

As the laser beam 160 applicable to the laser treatment according to this embodiment, a laser beam having a wavelength that is absorbed by the single crystal semiconductor layer is employed. The wavelength of a laser beam can be determined in consideration of the skin depth of the laser beam, or the like. For example, light having an emission wavelength in the range from ultraviolet region to visible light region is selected; typically, light having a wavelength in the range from 250 nm to 700 nm can be used. As a specific example of the laser beam 160, a laser beam emitted from a solid-state laser typified by a YAG laser or a YVO₄ laser, or an excimer laser (XeCl (308 nm), KrF (248 nm) can be given. In the case of using the solid-state laser, a second harmonic (532 nm), a third harmonic (355 nm), or a fourth harmonic (266 nm) is used. As the laser that emits the laser beam 160, a continuous wave laser, a quasi continuous wave laser, or a pulsed laser can be used. In order to form the partly-melted state, it is preferable to use a pulsed laser. For example, the following lasers can be used: a pulsed laser which can emit a laser beam having a repetition rate of 1 MHz or lower and a pulse width of 10 nsec to 500 nsec and XeCl excimer laser which can emit a laser beam having a repetition rate of 10 Hz to 300 Hz, a pulse width of 25 nesec, and a wavelength of 308 nm.

Further, the energy of the laser beam for irradiation of the single crystal semiconductor layer is determined based on the wavelength of the laser beam, the skin depth of the laser beam, and the thickness of the single crystal semiconductor layer which is to be irradiated. The energy of the laser beam can be, for example, in the range of 300 mJ/cm² to 800 mJ/cm² inclusive. For example, the energy density of the laser beam can be set at 600 mJ/cm² to 700 mJ/cm² inclusive in the case where the thickness of the single crystal semiconductor layer is approximately 120 nm, a pulsed laser is used as the laser, and a wavelength of the laser beam is 308 nm.

Irradiation with the laser beam 160 is preferably performed in an inert gas atmosphere such as a rare gas atmosphere or a nitrogen atmosphere or in a vacuum. Irradiation with the laser beam 160 in an inert gas atmosphere or in a vacuum can suppress generation of cracks in the single crystal semiconductor layer which is to be irradiated more effectively than irradiation with the laser beam in air. For example, in the case where irradiation with the laser beam 160 is performed in an inert gas atmosphere, the atmosphere in an airtight chamber is replaced with an inert gas atmosphere and irradiation with the laser beam 160 is performed. In the case where the chamber is not used, by blowing an inert gas such as a nitrogen gas to the surface irradiated with the laser beam 160 (the surface of the first single crystal semiconductor layer 121 in FIG. 4C), irradiation with the laser beam 160 in the inert gas atmosphere can be substantially realized.

The laser beam 160 preferably has a linear form on an irradiation surface with homogenous energy distribution using an optical system. By making the form of the laser beam 160 the linear form, the surface can be irradiated uniformly with high throughput. When the beam length of the laser beam 160 can be made larger than the length of one side of the base substrate 110, all the single crystal semiconductor layers provided over the base substrate 110 can be irradiated with the laser beam 160 by one scan. In the case where the beam length of the laser beam 160 is smaller than the length of one side of the base substrate 110, all the single crystal semiconductor layers formed over the base substrate 110 can be irradiated with the laser beam 160 by plural scans.

Note that heat treatment can be performed in combination with the laser treatment, which can lead to crystallinity recovery or damage repairing. The heat treatment is preferably performed using a heating furnace, an RTA apparatus, or the like at higher temperature and/or a longer time than the heat treatment for dividing the single crystal semiconductor substrate 101 at the embrittlement layer 105. Needless to say, the heat treatment is performed at a temperature that is not above the strain point of the base substrate 110.

Instead of the laser treatment, a means which is used to remove a damaged layer by etching may be used. By etching a surface layer of the single crystal semiconductor layer which is formed by being separated from the single crystal semiconductor substrate as a thin film, damaged portions formed by the formation of the embrittlement layer or division of the single crystal semiconductor substrate can be removed, and the surface of the single crystal semiconductor layer can be planarized.

The reduced thickness of the first single crystal semiconductor layer 121 (i.e., the thickness of a portion to be etched away) can be determined by a practitioner as appropriate. For example, the single crystal semiconductor substrate is divided to form the first single crystal semiconductor layer 121 with a thickness of approximately 300 nm, and then a portion of the first single crystal semiconductor layer which has a thickness of approximately 200 nm is etched from its surface layer, whereby the first single crystal semiconductor layer 121 with a thickness of approximately 100 nm without damaged portion is formed.

The thinning of the first single crystal semiconductor layer 121 can be conducted by dry etching or wet etching, preferably, dry etching.

For example, the dry etching is performed by a reactive ion etching (RIE) method, an inductively coupled plasma (ICP) etching method, an electron cyclotron resonance (ECR) etching method, a parallel plate (capacitive coupled plasma) etching method, a magnetron plasma etching method, a dual-frequency plasma etching method, or a helicon wave plasma etching method. As an etching gas, for example, a chlorine-based gas such as chlorine, boron chloride, or silicon chloride (including silicon tetrachloride), a fluorine-based gas such as trifluoromethane, carbon fluoride, nitrogen fluoride, or sulfur fluoride, a bromide-based gas such as hydrogen bromide, or the like can be given. Additionally, an inert gas such as helium, argon, or xenon; an oxygen gas; a hydrogen gas; and the like can be given.

Note that, after the first single crystal semiconductor layer 121 is made thin, the single crystal semiconductor layer can be irradiated with a laser beam so that crystallinity of the single crystal semiconductor layer can be further improved.

The crystallinity of the first single crystal semiconductor layer 121 formed by being separated from the single crystal semiconductor substrate 101 is reduced due to the formation of the embrittlement layer or separation of the single crystal semiconductor substrate. By the laser beam irradiation or the etching as described above, the crystallinity on the surface of the first single crystal semiconductor layer 121 can be recovered. The first single crystal semiconductor layer 121 serves as a seed layer in epitaxial growth, and thus the crystallinity of the second single crystal semiconductor layer 122 formed by the epitaxial growth can be improved by the improvement in the crystallinity of the first single crystal semiconductor layer 121r.

The first single crystal semiconductor layer 121 whose crystallinity is recovered is used as a seed layer when the second single crystal semiconductor layer 122, which is a substantial a light absorption layer, is grown. Alternatively, a polycrystalline semiconductor substrate (typically, a polycrystalline silicon substrate) can be used instead of the single crystal semiconductor substrate. In this case, the first single crystal semiconductor layer 121 is formed of a polycrystalline semiconductor (typically, a polycrystalline silicon).

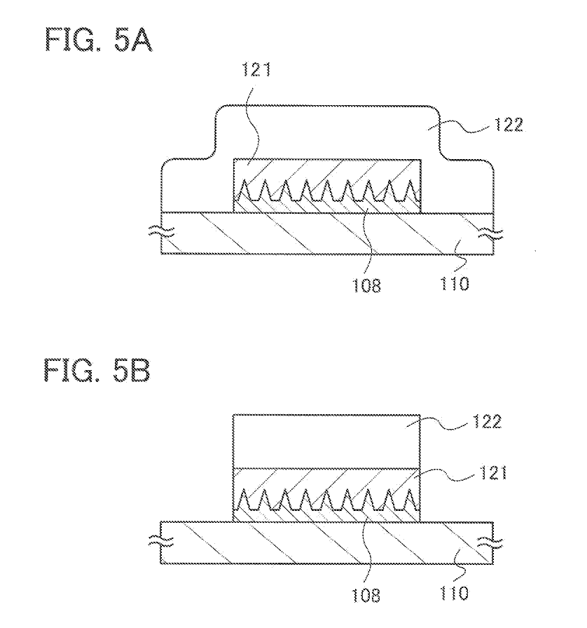

Next, the second single crystal semiconductor layer 122 is formed over the first single crystal semiconductor layer 121 (see FIG. 5A). Although a single crystal semiconductor layer having a desired thickness may be separated from a single crystal semiconductor substrate, the thickness of the single crystal semiconductor layer is preferably increased by epitaxial growth such as solid phase growth (solid phase epitaxial growth) or vapor phase growth (vapor phase epitaxial growth).

In the case of separating a thin layer of a single crystal semiconductor substrate by an ion implantation method or an ion doping method, acceleration voltage should be increased in order to increase the thickness of the single crystal semiconductor layer which is to be separated. However, there is a limitation of an increase in acceleration voltage of an ion implantation apparatus or an ion doping apparatus based on the apparatus. In addition, radiation rays might be generated due to an increase of the acceleration voltage, which raises a safety concern. Further, in a conventional apparatus, since it is difficult to perform irradiation with a large amount of ions with the acceleration voltage increased, a long period of time is needed for obtaining a predetermined amount of ions implanted, which may result in longer cycle time.

The above safety problems can be avoided by epitaxial growth. Further, the single crystal semiconductor substrate which is a source material can be left thick and the number of reusing can be increased, which leads to resource saving.

Since single crystal silicon which is a typical example of a single crystal semiconductor is an indirect transition semiconductor, its light absorption coefficient is lower than that of amorphous silicon which is a direct transition semiconductor. Accordingly, single crystal silicon is preferably at least several times as thick as amorphous silicon in order to absorb sufficient solar light. Here, the total thickness of the first single crystal semiconductor layer 121 and the second single crystal semiconductor layer 122 is 5 μm to 200 μm inclusive, preferably 10 μm to 100 μm inclusive.

A non-single-crystal semiconductor layer is formed by a chemical vapor deposition method typified by a plasma CVD method in the case where solid-phase epitaxial growth is employed. In a plasma CVD method, a microcrystal semiconductor or an amorphous semiconductor can be formed by changing deposition conditions such as the flow rate of the gases and applied power. For example, when the flow rate of the dilution gas (e.g., hydrogen) is 10 to 2000 times, preferably 50 to 200 times the flow rate of a semiconductor source gas (e.g., silane), a microcrystal semiconductor layer (typically, a microcrystal silicon layer) can be formed. When the flow rate of the dilution gas is less than 10 times the semiconductor source gas, an amorphous semiconductor layer (typically, an amorphous silicon layer) can be formed. In addition, by mixing a doping gas into a reaction gas, an n-type or p-type non-single-crystal semiconductor layer is formed and solid phase grown to form an n-type or p-type single crystal semiconductor layer.

The heat treatment can be performed with a heat treatment apparatus such as an RTA apparatus, a furnace, or a high-frequency generator. When an RTA apparatus is used, it is preferable that the process temperature be 500° C. to 750° C. inclusive and the process time be 0.5 minutes to 10 minutes inclusive. When a furnace is used, it is preferable that the process temperature be 500° C. to 650° C. inclusive and the process time be 1 hour to 4 hours inclusive.

The second single crystal semiconductor layer 122 can be formed by vapor phase epitaxial growth employing a plasma CVD method using the first single crystal semiconductor layer 121 as a seed layer.

The conditions of a plasma CVD method for the vapor phase epitaxial growth depend on the flow rates of gases included in a reaction gas, power to be applied, or the like. For example, the second single crystal semiconductor layer 122 with small stress which is not easily peeled can be formed in an atmosphere including a semiconductor source gas (silane) and a dilution gas (hydrogen), in which the flow rate of the dilution gas is equal to or less than five times that of the semiconductor source gas, preferably, equal to or greater than one time and equal to or less than four times that of the semiconductor source gas. By mixing a doping gas into the reaction gas, an n-type or p-type single crystal semiconductor layer can be formed by vapor phase growth.

As is illustrated in FIG. 5A, there is a region of the base substrate 110 which is not provided with the seed layer for epitaxial growth. The second single crystal semiconductor layer 122 of this embodiment may be epitaxially grown at least over the first single crystal semiconductor layer 121. Thus, the crystal state of the region which is not provided with the seed layer is not particularly limited.

Note that the conductivity type of the first single crystal semiconductor layer 121 is not limited. In this embodiment, the single crystal silicon substrate which forms the first single crystal semiconductor layer 121 and the single crystal layer over the single crystal silicon substrate are p-type. In addition, although the conductivity type of the second single crystal semiconductor layer 122 is not limited, in this embodiment, the second single crystal semiconductor layer 122 formed over the first single crystal semiconductor layer 121 is p-type. Note that in the case of forming a cell using a combination of conductivity types different from the combination of conductivity types of this embodiment, a single crystal silicon substrate which has a conductivity type different from the above or a single crystal layer which has a conductivity type different from the above may be employed.

Next, a region of the second single crystalline semiconductor layer 122, which is not formed over the first single crystalline semiconductor layer 121, is removed, whereby a stacked layer including the first single crystalline semiconductor layer 121 and the second single crystalline semiconductor layer 122 is formed. In the case where a plurality of the first single crystalline semiconductor layers 121 are disposed with respect to one base substrate 110, the above-described region and the second single crystalline semiconductor layer formed between the first single crystalline semiconductor layers 121 are removed, whereby the adjacent stacked layer are separated into the plural stacked layers. Accordingly, connecting to the adjacent stacked layers can be easily obtained later (see FIG. 5B).

The removal can be performed by laser beam irradiation or etching, and the means that is used in the above recovery of crystallinity of the surface of the first single crystal semiconductor layer 121 can be used; in the case of laser beam irradiation, the energy density is set higher and the region and the space between the first single crystalline semiconductor layers 121 is irradiated; in the case of etching, a protective layer is formed only over the stacked layers, and the etching time is set longer. Note that the entire semiconductor layer between the adjacent stacked layer is not necessarily removed as long as the stacked layers are electrically insulated substantially.

Here, since the second single crystal semiconductor layer 122 is formed by epitaxial growth using the first single crystal semiconductor layer 121 as a seed, the second single crystal semiconductor layer 122 and the first single crystal semiconductor layer 121 form a continuous single crystal semiconductor. However, each of them will be individually described and illustrated.

Next, diffusion regions of impurities to serve as an n-type semiconductor and a p-type semiconductor in a surface layer the second single crystal semiconductor layer 122, and semiconductor junction are formed. As an impurity element imparting n-type conductivity, phosphorus, arsenic, antimony, and the like, which belong to Group 15 in the periodic table, are typically given. As an impurity element imparting p-type conductivity, boron, aluminum, and the like, which belong to Group 13 in the periodic table, are typically given.

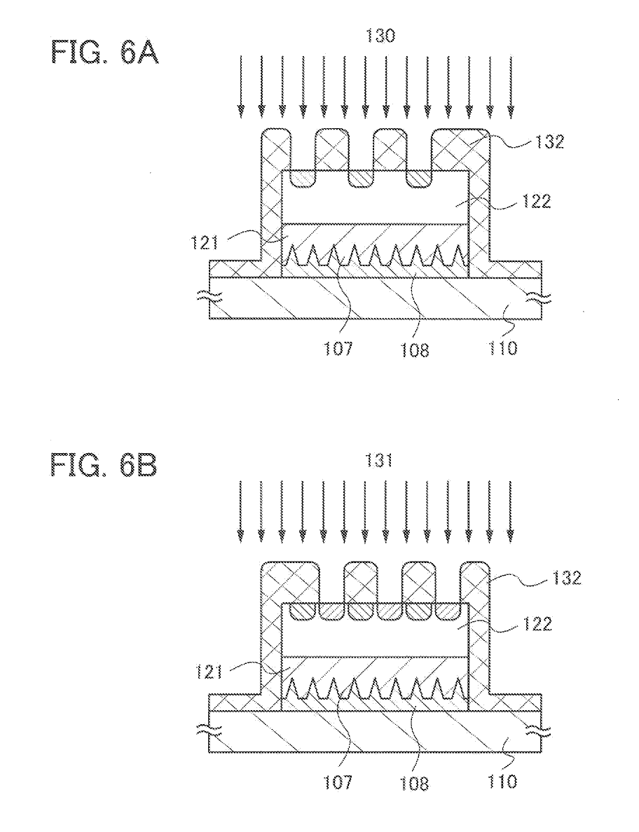

A photoresist 132 having openings for forming the first impurity semiconductor layer is provided as a protective layer over the second single crystal semiconductor layer 122, and a phosphorus ion 130 which imparts n-type conductivity is introduced by an ion doping method or an ion implantation method. The photoresist 132 is removed, and then a photoresist 133 having openings for forming the second impurity semiconductor layer is provided as a protective layer again, and a boron ion 131 which imparts p-type conductivity is introduced by an ion doping method or an ion implantation method (see FIGS. 6A and 6B).

For example, an ion doping apparatus by which generated ions are accelerated by voltage without mass separation and the substrate is irradiated with ions is used, and the phosphorus ion 130 is introduced using phosphine as a source gas. Here, hydrogen or helium may be added to phosphine which is a source gas. With use of an ion doping apparatus, the area to be irradiated with the ion beam can be enlarged, and treatment can be efficiently performed. For example, a linear ion beam whose length exceeds one side of the base substrate 110 is formed and delivered from one end to the other end of the base substrate 110; thus, the impurity can be introduced to the surface layer of the second single crystal semiconductor layer 122 at a uniform depth.

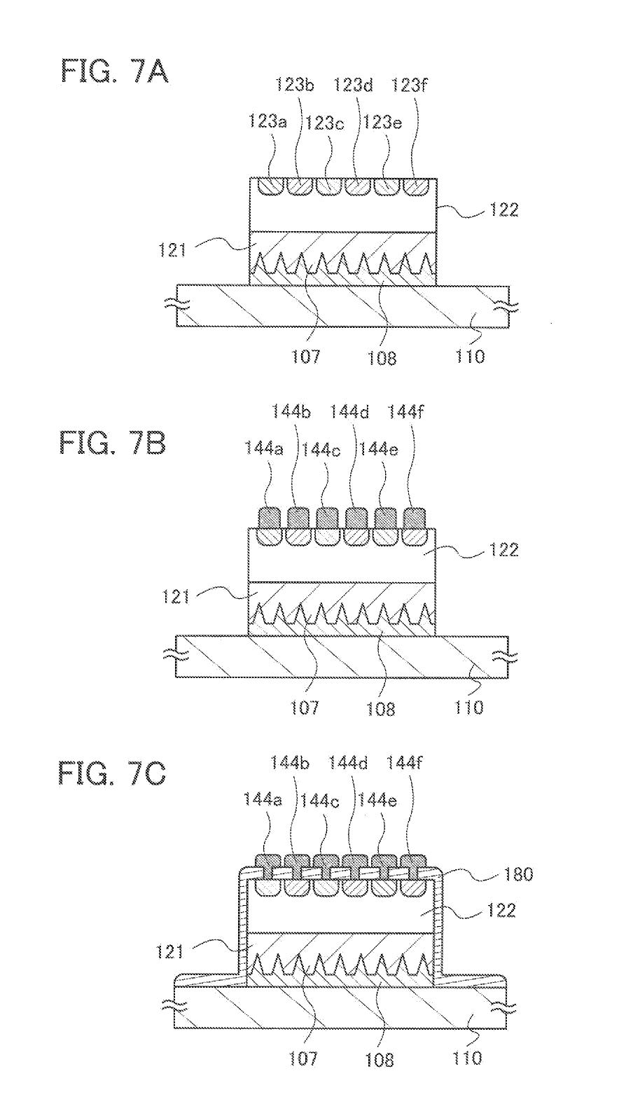

Next, a region to which the impurities are introduced is activated in a state illustrated in FIG. 7A. The activation is performed using heat treatment or laser beam irradiation so that the crystallinity of a region which is damaged due to introduction of the impurities is recovered and so that impurity atoms and semiconductor atoms are combined to provide conductivity.

In the case of heat treatment, the means that can be employed for dividing, at the embrittlement layer 105, the single crystal semiconductor substrate 101 provided with the embrittlement layer 105 after the single crystal semiconductor substrate 101 is bonded to the base substrate 110 can be employed. In the case of the laser beam irradiation, the means that can be employed for recovery of crystallinity of the surface of the first single crystal semiconductor layer 121 can be employed.

In this embodiment, the first single crystal semiconductor layer 121 is formed by separating a thin film from the p-type single crystal semiconductor substrate, and the p-type second single crystal semiconductor layer 122 is formed by epitaxial crystal growth of a single crystal semiconductor layer with the first single crystal semiconductor layer 121 serving as a seed layer. In addition, semiconductor layers including the impurity element imparting n-type conductivity and semiconductor layers including the impurity element imparting p-type conductivity are formed in the surface layer of the second single crystal semiconductor layer 122. Here, n-type conductivity is imparted to the first impurity semiconductor layers 123a, 123c, and 123e, whereas p-type conductivity is imparted to the second impurity semiconductor layers 123b, 123d, and 123f. As a result, the photoelectric conversion layer 120 of this embodiment has p-n junction formed between the second single crystal semiconductor layer 122 and the first impurity semiconductor layers 123a, 123c, and 123e.

The first electrodes 144a, 144c, and 144e which serve as negative electrodes are provided over the first impurity semiconductor layers 123a, 123c, and 123e formed by activation. Similarly, the second electrodes 144b, 144d, and 144f which serve as positive electrodes are provided over the second impurity semiconductor layers 123b, 123d, and 123f formed by activation. These electrodes are formed using a material including metal such as nickel, aluminum, silver, or solder. Specifically, these electrodes can be formed using a nickel paste, a silver paste, or the like by a screen printing method (see FIG. 7B).

As the structure illustrated in FIG. 7C, a protective film 180 to serve as a passivation layer may be formed over the impurity semiconductor layers and the protective film may be partly removed to have openings, so that the first electrodes 144a, 144c, and 144d and the second electrodes 144b, 144d, and 144f may be provided.

A semiconductor surface is in a state which may be referred to as lattice defects and has a number of surface states, which may lead to recombination of carriers at the vicinity of the surface; therefore, carriers at the vicinity of the semiconductor surface have a shorter lifetime than the carriers in an inner portion of the semiconductor. Accordingly, when the surface of the semiconductor layer of the photoelectric conversion device is exposed, carriers which are generated by photoelectric conversion are lost by surface recombination, and thus conversion efficiency is decreased. In order to suppress surface recombination, it is effective to form a protective film which serves as a passivation layer to form a good interface. The protective film also provides an effect of blocking impurities from the outside.

Specific examples of the protective film 180 to serve as a passivation layer which can be used in this embodiment include materials which have been given above as the materials for forming the insulating layer 108.

In this embodiment, an example in which the first impurity semiconductor layers 123a, 123c. and 123e are n-type semiconductors and the second impurity semiconductor layers 123b, 123d, and 123f are p-type semiconductors is described; but obviously the n-type semiconductors and the p-type semiconductors can be replaced with each other.

Although the epitaxially grown second single crystal semiconductor layer 122 has p-type conductivity in the example of this embodiment, the second single crystal semiconductor layer 122 can alternatively have n-type or i-type conductivity.

Thus, the photoelectric conversion device illustrated in FIG. 1A can be formed.

Note that this embodiment can be combined as appropriate with any of the other embodiments.

### Embodiment 2

One embodiment of the present invention relates to a photoelectric conversion device having a single crystal semiconductor layer. In the photoelectric conversion device, a light-transmitting insulating substrate is used as a support substrate, semiconductor junction and electrodes are formed on the semiconductor layer surface side, and a light-receiving surface is the supporting substrate side.

In this embodiment, a method for manufacturing a photoelectric conversion module will be described in details with reference to drawings.

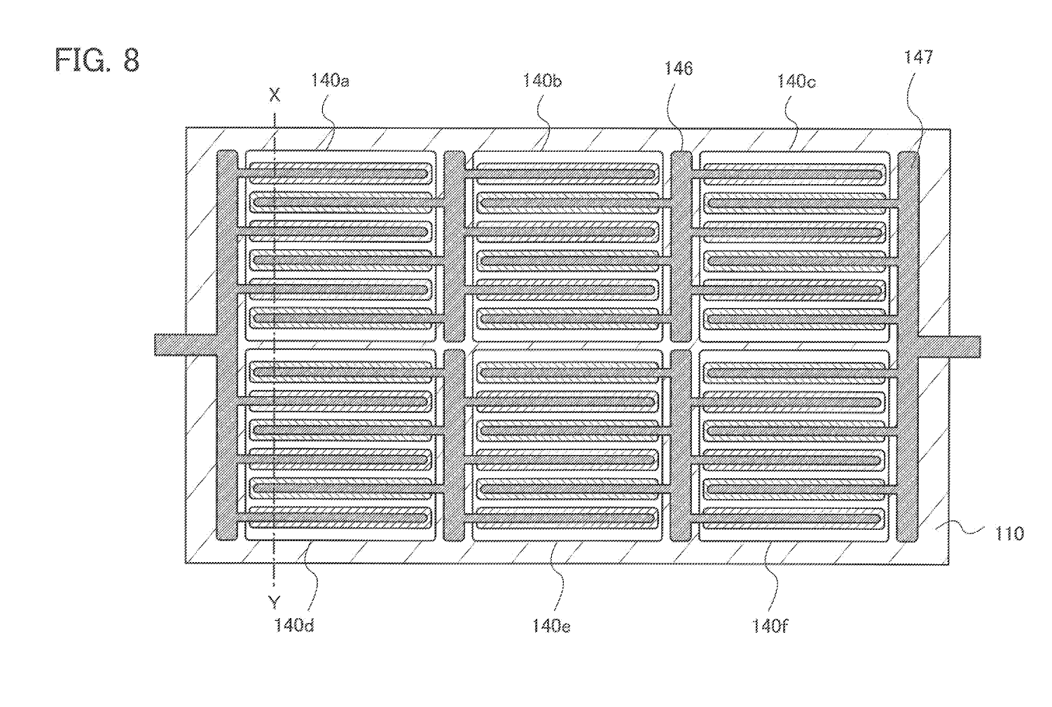

FIG. 8 illustrates an example in which a plurality of planar photoelectric conversion layers are arranged over one substrate having an insulating surface at predetermined intervals. In the example, electrodes are formed for a plurality of photoelectric conversion layers and they are connected in series to form a unit and the units are connected in parallel. A positive terminal and a negative terminal which extract power from the photoelectric conversion layers connected in series and in parallel are also provided. Note that the number of photoelectric conversion layers provided over the substrate, an area of each photoelectric conversion layer, a method for connecting the photoelectric conversion layers, a method for extracting power from the photoelectric conversion module, and the like are not particularly limited and a practitioner may determine them as appropriate in accordance with desired power, an installation site, or the like.

In this embodiment, an example in which photoelectric conversion layers 140a, 140b, 140c, 140d, 140e, and 140f are arranged over the base substrate 110 at predetermined intervals is illustrated. In the illustrated example, the adjacent photoelectric conversion layers are electrically connected to each other; two units in each of which three photoelectric conversion layers are connected in series are arranged, and the two units of the photoelectric conversion layers are connected in parallel.

There are no particular limitations on a base substrate 110 as long as the substrate can withstand a manufacturing process of the photoelectric conversion device according to one embodiment of the present invention and transmit light; for example, a light-transmitting insulating substrate can be used. Specifically, various glass substrates used in the electronics industry, such as substrates formed of aluminosilicate glass, aluminoborosilicate glass, and bariumborosilicate glass can be given, as well as a quartz substrate, a ceramic substrate, a sapphire substrate, and the like. A glass substrate, which can have a large area and is inexpensive, is preferably used because a cost reduction and productivity improvement can be achieved.

As the steps from the preparation of the single crystal semiconductor substrate 101 up to the formation of the insulating layer 108 in FIG. 3C, the steps described in Embodiment 1 can be employed. Note that also in this embodiment, as in Embodiment 1, the single crystal semiconductor substrate 101 and the single crystal semiconductor layer 107 in FIG. 3A form a continuous structure and they are collectively referred to as the single crystal semiconductor substrate 101 hereinafter.

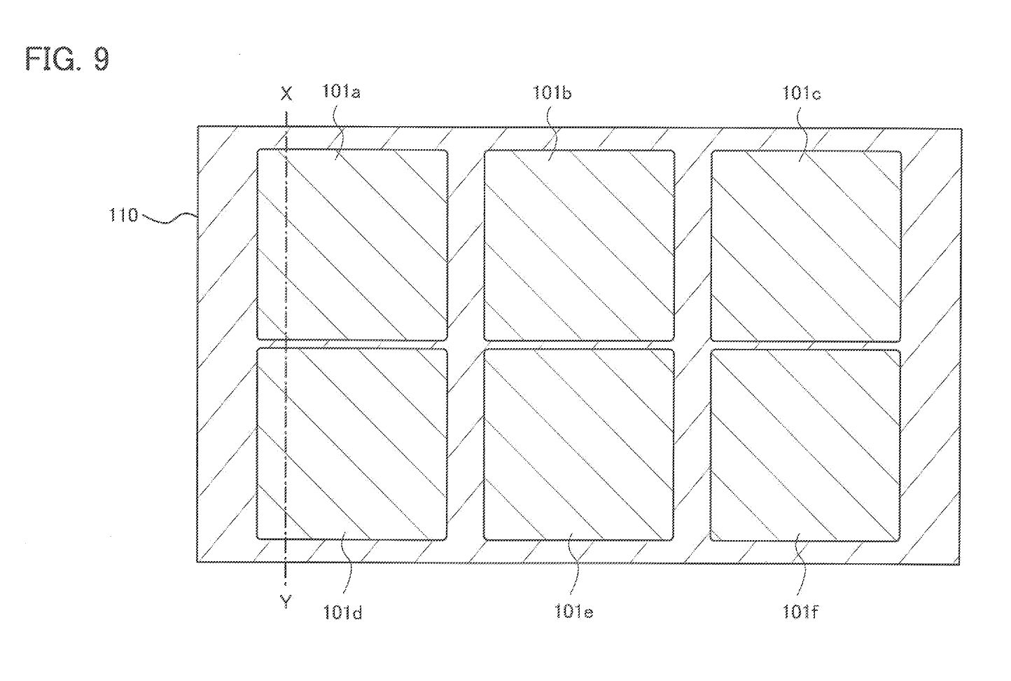

One surface of the single crystal semiconductor substrate 101 and one surface of the base substrate 110 are made to face each other and superposed. In one embodiment of the present invention, the photoelectric conversion module in which a plurality of photoelectric conversion layers are provided over one substrate is manufactured. Therefore, a plurality of single crystal semiconductor substrates 101 are attached to the base substrate 110 at predetermined intervals. FIG. 9 illustrates the case where six single crystal semiconductor substrates 101 are arranged over one base substrate 110 at predetermined intervals as an example. Here, for descriptive purposes, the six single crystal semiconductor substrates 101 are referred to as a single crystal semiconductor substrate 101a, a single crystal semiconductor substrate 101b, a single crystal semiconductor substrate 101c, a single crystal semiconductor substrate 101d, a single crystal semiconductor substrate 101e, and a single crystal semiconductor substrate 101f.

The interval between the adjacent single crystal semiconductor substrates (e.g., the single crystal semiconductor substrates 101a and 101d) is approximately 1 mm.

As the following steps from the attachment of the base substrate 110 and the single crystal semiconductor substrate 101 up to the planarization of the surface, the steps described in Embodiment 1 with reference to FIGS. 4A to 4C can be employed. As illustrated in FIG. 9, the single crystal semiconductor substrates 101a to 101f are arranged over one base substrate 110, and a plurality of stacked layers in which the insulating layer 108 and the first single crystal semiconductor layer 121 are sequentially formed is provided over the base substrate 110, in accordance with the arrangement of the single crystal semiconductor substrates.

Note that in the case where the beam length of the laser beam 160 is shorter than one side of the base substrate 110 in FIG. 4C, all the single crystal semiconductor layers formed over the base substrate 110 can be irradiated with the laser beam 160, by performing scanning plural times.

Instead of laser treatment, a means which is used to remove a damaged layer employing etching may also be used. Also in this case, the method described in Embodiment 1 can be employed.

The planarity and crystallinity of the single crystal semiconductor layer formed being separated from the single crystal semiconductor substrate is reduced due to the formation of the embrittlement layer or division of the single crystal semiconductor substrate. Thus, by the laser beam irradiation or the etching as described above, the planarity and crystallinity on the surface of the first single crystal semiconductor layer 121 can be recovered. The first single crystal semiconductor layer 121 can serve as a seed layer in epitaxial growth, and thus the crystallinity of the semiconductor layer formed by the epitaxial growth can be improved by the improvement in surface planarity and crystallinity of the semiconductor layer.

As a semiconductor layer which is a substantial light absorption layer, the second single crystal semiconductor layer 122 is formed over the first single crystal semiconductor layer 121. As this step, the step described in Embodiment 1 with reference to FIG. 5A can be employed.

Since single crystal silicon which is a typical example of a single crystal semiconductor is an indirect transition semiconductor, its light absorption coefficient is lower than that of amorphous silicon which is a direct transition semiconductor. Accordingly, single crystal silicon is preferably at least several times as thick as amorphous silicon in order to absorb sufficient solar light. Here, the total thickness of the first single crystal semiconductor layer 121 and the second single crystal semiconductor layer 122 is 5 μm to 200 μm inclusive, preferably 10 μm to 100 μm inclusive.

A semiconductor layer is formed over the plurality of stacked layers (the insulating layer 108 and the first single crystal semiconductor layer 121) and over regions between the adjacent stacked layers. Note that in this step, a single crystal semiconductor layer is formed at least over the plurality of stacked layers. Here, the single crystal semiconductor layer which is formed over the stack is the second single crystal semiconductor layer 122. The second single crystal semiconductor layer 122 is formed by epitaxial growth using the first single crystal semiconductor layer 121 as a seed layer.

The method for epitaxial growth of the second single crystal semiconductor layer 122 has been described in Embodiment 1.

A plurality of stacked layers (the insulating layer 108 and the first single crystal semiconductor layer 121) are arranged over the base substrate 110 at predetermined intervals, and there is a region which is not provided with a seed layer for epitaxial growth. The second single crystal semiconductor layer 122 of this embodiment may be epitaxially grown at least over the first single crystal semiconductor layer 121. Thus, the crystal state of the region which is not provided with the seed layer is not particularly limited.

Note that the conductivity type of the first single crystal semiconductor layer 121 is not limited. In this embodiment, the single crystal silicon substrate and the single crystal layer over the single crystal silicon substrate, which form the first single crystal semiconductor layer 121, are p-type. In addition, the conductivity type of the second single crystal semiconductor layer 122 is not limited; in this embodiment, the single crystal layer formed over the first single crystal semiconductor layer 121 is p-type. Note that in the case of forming a cell using a combination of conductivity type different from that of this embodiment, a single crystal silicon substrate which has a conductivity types different from that of the above or a single crystal layer which has a conductivity type different from that of the above may be employed.

The semiconductor layer formed between the adjacent stacked layers makes the adjacent stacked layers connected and hinders later integration; therefore, the adjacent stacked layers are separated into the original number of stacked layers again (see FIG. 5B).

The separation can be performed by laser beam irradiation or etching. Specifically, the means that is used in the above recovery of crystallinity of the surface of the first single crystal semiconductor layer 121 can be used; in the case of laser beam irradiation, the energy density is set higher and the space between the adjacent stacked layers is irradiated; in the case of etching, a protective layer is selectively formed over the stacked layers in the region having the first single crystal semiconductor layer 121, and the etching time is set longer; thus the processing is performed. Alternatively, the means for selectively etching the amorphous regions which is described in Embodiment 1 may be used. Note that the entire semiconductor layer between the adjacent stacked layers is not necessarily removed as long as the stacked layers are electrically insulated substantially.

Next, diffusion regions of an impurity imparting n-type conductivity and an impurity imparting p-type conductivity are formed in the surface layer of the second single crystal semiconductor layer 122 to form semiconductor junction. A method for forming junction has been described in Embodiment 1 (see FIGS. 6A and 6B).

In this embodiment, the first single crystal semiconductor layer 121 is formed by separating a thin film from the single crystal semiconductor substrate, and the p-type second single crystal semiconductor layer 122 is formed by epitaxial growth with the first single crystal semiconductor layer 121 serving as a seed layer. In addition, semiconductor layers including the impurity element imparting n-type conductivity and semiconductor layers including the impurity element imparting p-type conductivity are formed in the surface layer of the second single crystal semiconductor layer 122. Here, n-type conductivity is imparted to the first impurity semiconductor layers 123a, 123c, and 123e, whereas p-type conductivity is imparted to the second impurity semiconductor layers 123b, 123d, and 123f. As a result, the photoelectric conversion layer 120 of this embodiment has p-n junction formed between the second single crystal semiconductor layer 122 and the first impurity semiconductor layers 123a, 123c, and 123e (see FIG. 7A).

The first electrodes 144a, 144c, and 144e which serve as negative electrodes are provided over the first impurity semiconductor layers 123a, 123c, and 123e formed by activation. Similarly, the second electrodes 144b, 144d, and 144f which serve as positive electrodes are provided over the second impurity semiconductor layers 123b, 123d, and 123f formed by activation. These electrodes are formed using a material including metal such as nickel, aluminum, silver, or solder. Specifically, these electrodes can be formed using a nickel paste, a silver paste, or the like by a screen printing method (see FIG. 7B).

A first connection electrode 146 which connects the adjacent photoelectric conversion layers in series and a second connection electrode 147 which connects the adjacent photoelectric conversion layers in parallel are formed using the same layer as that of the first electrodes 144a, 144c, and 144e and the second electrodes 144b, 144d, and 144f (see FIG. 8). Here, although these electrodes formed in individual photoelectric conversion layers and these connection electrodes are formed as one component, different names are given to them for convenience. Needleless to say, the connection electrode can be formed with a different layer from these electrodes.

Thus, the photoelectric conversion device module illustrated in FIG. 8 can be formed.

Light which passes through the light-transmitting base substrate 110 generates carriers in the first single crystal semiconductor layer 121 and the second single crystal semiconductor layer 122, which is a substantial light absorption layer. The generated carriers can move to a region where an internal electric field is formed by the second single crystal semiconductor layer 122 and the first impurity semiconductor layers 123a, 123c, and 123e. The carriers are extracted as current from the first electrodes 144a, 144c, and 144e and the second electrodes 144b, 144d, and 144f. Only the insulating layer 108 having a light-transmitting property is interposed between the light-transmitting base substrate 110 and the first single crystal semiconductor layer 121; therefore, a highly efficient photoelectric conversion device without a loss due to the shadow of a collection electrode can be manufactured.

In addition, the single crystal semiconductor substrate from which the single crystal semiconductor layer is separated can be reused. Thus, a resource-saving type photoelectric conversion device and photoelectric conversion module which allow a semiconductor material to be effectively used can be manufactured. In addition, the cell includes the single crystal semiconductor layer which is bonded to the base substrate with the insulating layer interposed therebetween without an adhesive; therefore, the photoelectric conversion module having high mechanical strength as well as improved conversion efficiency can be provided.

In this embodiment, an example in which the first impurity semiconductor layers 123a, 123c, and 123e are n-type semiconductors and the second impurity semiconductor layers 123b, 123d, and 123f are p-type semiconductors is described; but obviously the n-type semiconductors and the p-type semiconductors can be replaced with each other.

Although the epitaxially grown second single crystal semiconductor layer 122 has p-type conductivity in an example of this embodiment, the second single crystal semiconductor layer 122 can alternatively have n-type or i-type conductivity.

Note that this embodiment can be combined as appropriate with any of the other embodiments.

### Embodiment 3

In this embodiment, an example of a photoelectric conversion device and a manufacturing method thereof which is different from that described in Embodiment 2 will be described. Note that a description of the same components as those of the above embodiment is omitted or partly simplified.

By the steps according to Embodiment 1, stacked layers including the insulating layer 108, the first single crystal semiconductor layer 121, and the second single crystal semiconductor layer 122 are formed over the base substrate 110 (see FIG. 5B).

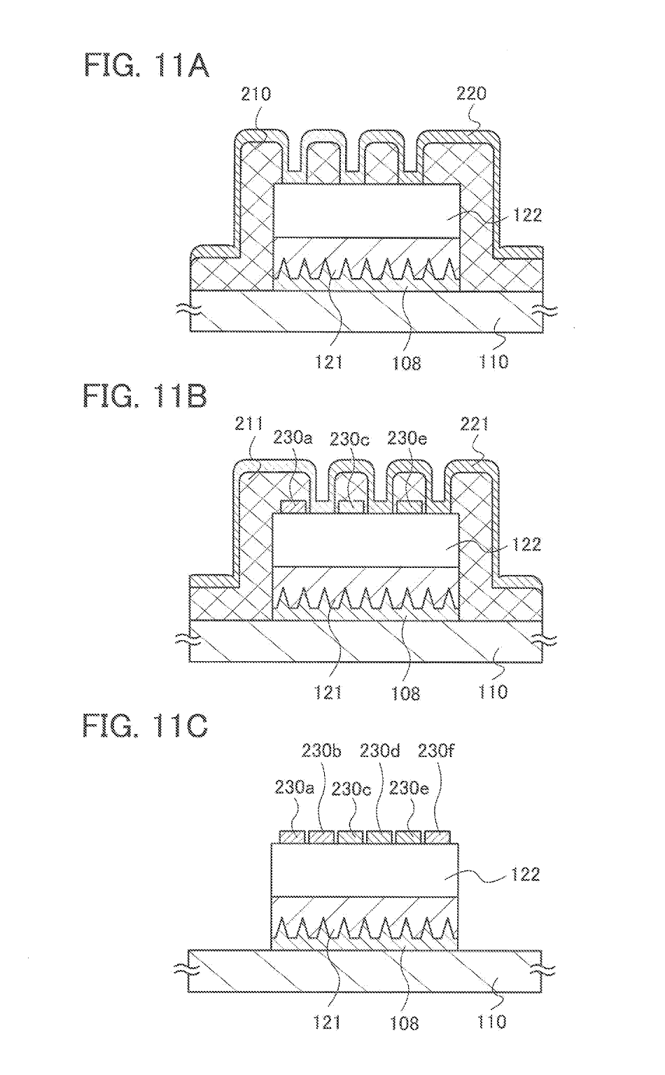

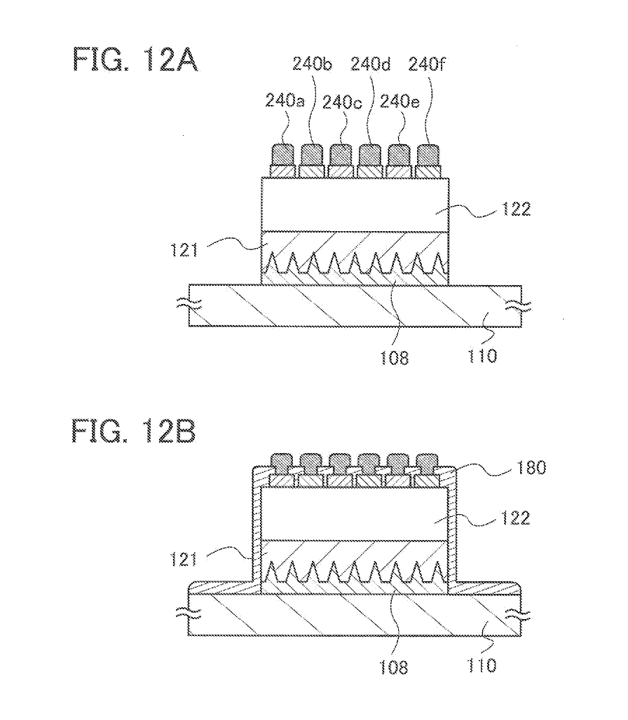

Over the stacked layers, first impurity semiconductor layers 230a, 230c, and 230e and second impurity semiconductor layers 230b, 230d, and 230f are alternately formed in stripes without overlapping with each other. Over the impurity semiconductor layers, first electrodes 240a, 240e, and 240e and second electrodes 240b, 240d, and 240f are formed, whereby the photoelectric conversion device can be completed (see FIGS. 11A, 11B, and 11C and FIG. 12A).

In a bulk photoelectric conversion device, an impurity semiconductor layer having one conductivity type is formed in a bulk having a conductivity type which is opposite to the one conductivity type of the impurity semiconductor layer, and an internal electric field which is needed for transfer of carriers is formed in a depletion layer generated at the formed p-n junction interface. The impurity semiconductor layers can be formed in a manner similar to that of a thin film photoelectric conversion device, and by forming p-n junction or p-i-n junction, an internal electric field can be formed between a p-type semiconductor layer and an n-type semiconductor layer.

A specific example of a manufacturing method will be described. The structure illustrated in FIG. 5B is formed, and a photoresist 210 having stripe openings at predetermined intervals is formed over the second single crystal semiconductor layer 122, then, a first impurity semiconductor layer 220 is formed on the entire surface (see FIG. 11A). An unnecessary film is removed by a lift-off method; then, the first impurity semiconductor layers 230a, 230c, and 230e are formed. A photoresist 211 having stripe openings which are different from those of the photoresist 210 is formed over the second single crystal semiconductor layer 122 provided with the first impurity semiconductor layers 230a, 230c, and 230e. The second impurity semiconductor layer 221 is formed on the entire surface (see FIG. 11B). An unnecessary film is removed again by a lift-off method. Thus, a structure is employed in which the first impurity semiconductor layers 230a, 230c, and 230e and the second impurity semiconductor layers 230b, 230d, and 230f which do not overlap with each other are alternately formed in stripes over the stacked layers (see FIG. 11C). Lastly, the first electrodes 240a, 240c, and 240e and the second electrodes 240b, 240d, and 240f are formed, whereby the photoelectric conversion device is completed (see FIG. 12A).

In this embodiment, the second single crystal semiconductor layer 122 is formed to have p-type conductivity. For the first impurity semiconductor layer 220, a non-single-crystal semiconductor layer is formed by a plasma CVD method using silane and phosphine including an impurity element imparting n-type conductivity (e.g., phosphorus) as a source gas. In addition, for a second impurity semiconductor layer 221, a non-single-crystal semiconductor layer is formed by a plasma CVD method using silane and diborane including an impurity element imparting p-type conductivity (e.g., boron); thus, p-n junction is formed.

Note that before forming the first impurity semiconductor layer 220 and the second impurity semiconductor layer 221 by a plasma CVD method or the like, a material layer such as a native oxide layer, which is not a semiconductor, on the second single crystal semiconductor layer 122 is removed. The native oxide layer can be removed by wet etching using hydrofluoric acid or by dry etching. Alternatively, before a semiconductor source gas is introduced at the step of forming the first impurity semiconductor layer 220 and the second impurity semiconductor layer 221, plasma treatment may be performed using a mixed gas of hydrogen and a rare gas, for example, a mixed gas of hydrogen and helium or a mixed gas of hydrogen, helium, and argon. By such plasma treatment, a native oxide layer on the second single crystal semiconductor layer 122 or an element in the atmosphere (oxygen, nitrogen, or carbon) adsorbed to the second single crystal semiconductor layer 122 can be removed.

In this embodiment, the first impurity semiconductor layer 220 and the second impurity semiconductor layer 221 which are formed over the second single crystal semiconductor layer 122 may be subjected to heat treatment or laser beam irradiation so as to be improved in crystallinity or activated. Note that impurities included in the impurity semiconductor layers can be diffused into the surface layer of the second single crystal semiconductor layer 122 by the heat treatment or the laser beam irradiation, and a junction interface can be formed again in the single crystal layer, whereby a favorable interface can be obtained.

In this embodiment, a lift-off method using a photoresist is given as an example; however, the structure illustrated in FIG. 11C may be formed performing a film formation step, photolithography step, etching step, and the like for the impurity semiconductor layers.

As the structure illustrated in FIG. 12B, the protective film 180 to serve as a passivation layer may be formed over the impurity semiconductor layers and the protective film may be partly removed to have openings, so that the first electrodes 240a, 240c, and 240e and the second electrodes 240b, 240d, and 240f can be provided.

In this embodiment, an example in which the first impurity semiconductor layers 230a, 230c, and 230e serve as n-type semiconductors and the second impurity semiconductor layers 230b, 230d, and 230f serve as p-type semiconductors is described; but the n-type semiconductors and the p-type semiconductors can be replaced with each other obviously.

Although an example in which the second single crystal semiconductor layer 122 has p-type conductivity and p-n junction is formed is described in this embodiment; however, the second single crystal semiconductor layer 122 can alternatively have n-type or i-type conductivity.

In this manner, the semiconductor layers each including a dopant are selectively formed over the stacked layers in which the insulating layer, the first single crystal semiconductor layer, and the second single crystal semiconductor layer are sequentially formed over the base substrate, whereby a photoelectric conversion device provided in which a plurality of impurity semiconductor layers having different conductivity types that is formed on the surface layer of the single crystal semiconductor layer, and in which a light-receiving surface is the supporting substrate side.

Note that this embodiment can be combined as appropriate with any of the other embodiments.

### Embodiment 4

In this embodiment, an example of a method for manufacturing a photoelectric conversion device, which is different from that described in the above embodiments, will be described. Specifically, a method for forming a modified region to serve as an embrittlement layer in a single crystal semiconductor substrate with use of multiphoton absorption will be described. Note that a description of the same components as those of the above embodiment is omitted or partly simplified.

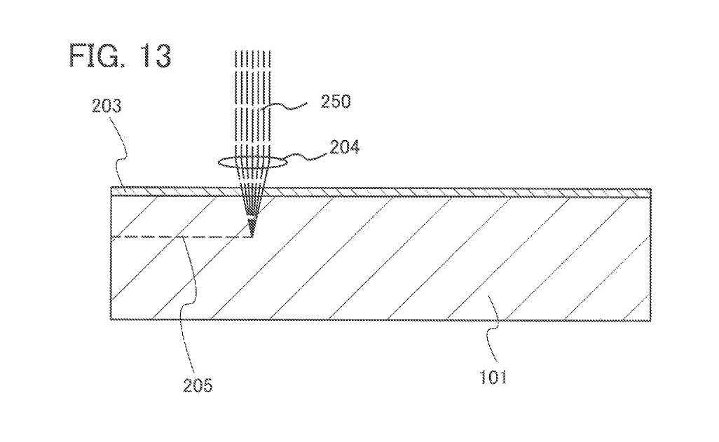

As illustrated in FIG. 13, the single crystal semiconductor substrate 101 is irradiated with a laser beam 250 from the side of the surface on which an insulating layer 203 is formed, and the laser beam 250 is condensed inside the single crystal semiconductor substrate with an optical system 204. The entire surface of the single crystal semiconductor substrate 101 is irradiated with the laser beam 250, whereby a modified region 205 is formed in a region at a predetermined depth of the single crystal semiconductor substrate 101. A laser beam which allows multiphoton absorption is employed as the laser beam 250. The modified region 205 has the same state as the embrittlement layer 105.

The multiphoton absorption is a phenomenon in which a substance absorbs a plurality of photons at the same time and energy of the substance has a higher energy level than the energy before light absorption. As the laser beam 250 that allows multiphoton absorption, a laser beam emitted from a femtosecond laser is used. Multiphoton absorption is known as one of the nonlinear interactions which are made by a femtosecond laser. Multiphoton absorption can generate a reaction in a localized region near the focal point, and thus the modified region can be formed in a desired region. For example, irradiation with the laser beam 250 that allows multiphoton absorption can form the modified region 205 having voids with approximately several nanometers.

In the formation of the modified region 205 utilizing multiphoton absorption, the depth of the modified region 205 formed in the single crystal semiconductor substrate 101 is determined depending on the position of the focal point of the laser beam 250 (the depth at which the laser beam 250 is focused in the single crystal semiconductor substrate 101). The position at which the laser beam 250 is focused can be easily adjusted by a practitioner using the optical system 204.

As in this embodiment, by the formation of the modified region 205 using multiphoton absorption, damages to regions other than the modified region 205 and generation of crystal defects can be prevented. Thus, a single crystal semiconductor layer having favorable characteristics, for example, crystallinity can be formed by division at the modified region 205.

Note that it is preferable that the insulating layer 203 formed of an oxide layer such as a silicon oxide layer or a silicon oxynitride layer be formed over the single crystal semiconductor substrate 101, and irradiation with the laser beam 250 be conducted through the insulating layer 203. Further, the following formula (1) is preferably satisfied where the wavelength of the laser beam 250 is λ (nm), the refractive index of the insulating layer 203 at the wavelength λ (nm) is n, and the thickness of the insulating layer 203 is d (nm).

[FORMULA 1]

d=λ/4n×(2m+1) (m is an integer of 0 or more) (1)

By forming the insulating layer 203 so as to satisfy the formula (1), reflection of the laser beam 250 off the surface of the object (the single crystal semiconductor substrate 101) can be suppressed. As a result, the modified region 205 can be efficiently formed inside the single crystal semiconductor substrate 101.

After the modified region 205 is formed, the photoelectric conversion device can be formed according to another embodiment.

Note that the division of the single crystal semiconductor substrate 101 can be conducted by application of external force instead of heat treatment. Specifically, by application of physical and external force, the single crystal semiconductor substrate 101 can be divided at the modified region 205. For example, the thin single crystal semiconductor substrate 101 can be divided with a human hand or a tool. The modified region 205 is weakened due to voids or the like formed by irradiation with the laser beam 250. Therefore, by application of physical force (external force) to the single crystal semiconductor substrate 101, a weakened portion such as the voids in the modified region 205 as a trigger or a starting point which allows the single crystal semiconductor substrate 101 to be divided at the modified region 205. The single crystal semiconductor substrate 101 can be divided also by combination of heat treatment and application of external force. The division of the single crystal semiconductor substrate 101 by application of external force makes it possible to reduce time needed for the division, which can lead to an improvement in productivity.

Note that this embodiment can be combined as appropriate with any of the other embodiments.

### Embodiment 5

In this embodiment, an example of a method for manufacturing a photoelectric conversion device, which is different from that described in the above embodiments, will be described. Note that a description of the same components as those of the above embodiment is omitted or partly simplified.

The single crystal semiconductor substrate 101 is formed in which the embrittlement layer 105 is formed in a region at a predetermined depth and on one surface of which the insulating layer 108 is formed, according to Embodiment 2 (see FIG. 3C).

Then, planarizing treatment is performed by plasma treatment on the surface of the insulating layer 108 over the single crystal semiconductor substrate 101.

Specifically, an inert gas (e.g., an Ar gas) and/or a reaction gas (e.g., an O₂ gas or an N₂ gas) are/is introduced into a vacuum chamber, bias voltage is applied to an object (here, the single crystal semiconductor substrate 101 over which the insulating layer 108 is formed), and plasma is irradiated. Plasma includes electrons and cations of Ar, and the cations of Ar are accelerated toward a cathode (toward the single crystal semiconductor substrate 101 over which the insulating layer 108 is formed). The accelerated cations of Ar collide with the surface of the insulating layer 108 so that the surface of the insulating layer 108 is etched by sputtering. At this time, projections of the surface of the insulating layer 108 are preferentially etched by sputtering; thus, the planarity of the surface of the insulating layer 108 can be improved. In the case where a reaction gas is introduced, a defect generated due to the sputter etching performed on the surface of the insulating layer 108 can be repaired.

By the planarizing treatment by plasma treatment, the average surface roughness (Ra) of the surface of the insulating layer 108 can be, for example, 5 nm or less, preferably 0.3 nm or less. In addition, the maximum peak-to-valley distance (P-V) is 6 nm or less, preferably 3 nm or less

As an example of the plasma treatment, the following conditions can be employed: an electric power for the treatment is 100 W to 1000 W inclusive, a pressure is 0.1 Pa to 2.0 Pa inclusive, a gas flow rate is to 5 sccm to 150 sccm inclusive, and a bias voltage is 200 V to 600 V inclusive.

After the planarizing treatment, as illustrated in FIG. 4A, the surface of the insulating layer 108 formed over the single crystal semiconductor substrate 101 and the surface of the base substrate 110 are bonded so that the single crystal semiconductor substrate 101 is attached to the base substrate 110. In this embodiment, the planarity of the surface of the insulating layer 108 is improved so that a strong bond can be formed.

The planarizing treatment described in this embodiment may be performed on the base substrate 110. Specifically, plasma treatment may be performed with application of a bias voltage to the base substrate 110 to improve the planarity.

Note that this embodiment can be combined as appropriate with any of the other embodiments.

### Embodiment 6

In this embodiment, an example of a method for manufacturing a photoelectric conversion device, which is different from that described in the above embodiments, will be described. Note that a description of the same components as those of the above embodiment is omitted or partly simplified.

According to Embodiment 1, the stack including insulating layer 108, the first single crystal semiconductor layer 121, and the second single crystal semiconductor layer 122 is formed over the base substrate 110 (see FIG. 5B).

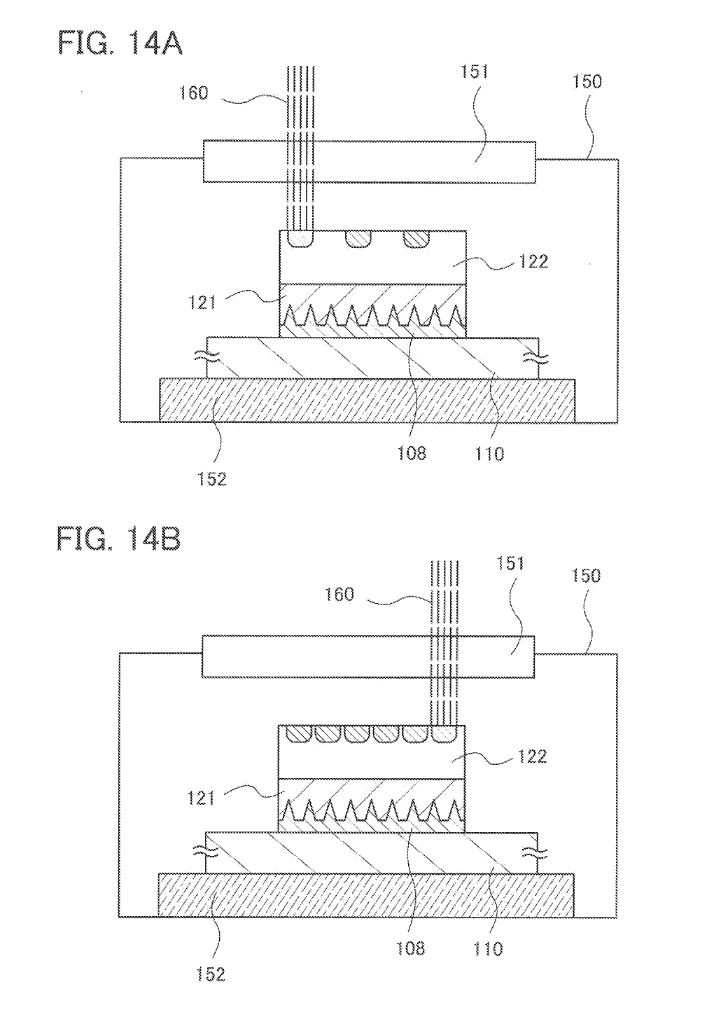

The base substrate 110 is placed in a vacuum chamber 150, which is provided with a window 151 for laser beam irradiation and a heater 152 for substrate heating, in a manner such that the surface provided with the stack faces upwards. The atmosphere in the vacuum chamber 150 is replaced with a doping gas, and the laser beam 160 is selectively delivered, whereby the impurity semiconductor regions are formed (see FIGS. 14A and 14B).

When the single crystal semiconductor layer is irradiated with a laser beam having a wavelength that is absorbed by the single crystal semiconductor layer, a phenomenon called melt-solidification occurs in the vicinity of the surface. This process of melt-solidification is greatly affected by the atmosphere and an element included in the atmosphere is taken as impurities into the semiconductor layer which is melt in some cases. In this phenomenon, an impurity element taken into the semiconductor layer can change the conductivity type if the impurity element is a Group 13 element or a Group 15 element. Therefore, when this method is used, even if a specific apparatus such as an ion doping apparatus or an ion implantation apparatus is not used, the impurity can be introduced into the semiconductor layer.

Note that as an impurity which imparts n-type conductivity to the semiconductor layer, a Group 15 element such as phosphorus (P), arsenic (As), or antimony (Sb) can be given. In addition, as an impurity which imparts p-type conductivity to the semiconductor layer, a Group 13 element such as boron (B), aluminum (Al), or gallium (Ga) can be given.

As a compound gas including the above impurity element, phosphine (PH₃), phosphorus trifluoride (PF₃), phosphorus trichloride (PCl₃), arsine (AsH₃), arsenic trifluoride (AsF₃), arsenic trichloride (AsCl₃), stibine (SbH₃), antimony trichloride (SbCl₃), and the like which includes a Group 15 element can be given. In addition, diborane (B₂H₆), boron trifluoride (BF₃), boron trichloride (BCl₃), aluminum trichloride (AlCl₃), gallium trichloride (GaCl₃), and the like which includes a Group 13 element can be given.

Alternatively, a mixed gas in which the compound gas including the impurity element is diluted with hydrogen, nitrogen, and/or a rare gas may be used in order to adjust the concentration of the impurity to be introduced into the semiconductor layer. The mixed gas may be used under reduced pressure.

When the impurity semiconductor layers which are formed first have n-type conductivity, the atmosphere in the vacuum chamber 150 is replaced with a mixed gas in which phosphine which is an n-type dopant gas is diluted with hydrogen, and the semiconductor layer is irradiated with a laser beam with a band shape, whereby the first impurity semiconductor layers 123a, 123c, and 123e are formed. Then, the atmosphere in the vacuum chamber 150 is replaced with a mixed gas in which diborane that is a p-type dopant gas is diluted with helium, and the semiconductor layer is irradiated with the laser beam 160 in stripes, whereby the second impurity semiconductor layers 123b, 123d, and 123f are formed. Thus, the structure illustrated in FIG. 7A is formed.

As for a laser and an irradiation method which can be used in this embodiment, the means which can be used for the recovery of crystallinity of the surface of the first single crystal semiconductor layer 121 in Embodiment 1 can be used.

Alternatively, as a means to promote melt-solidification by laser beam irradiation, a substrate may be heated with the heater 152 for substrate heating. Heating a substrate has an effect of decreasing the melt threshold energy at the time of laser beam irradiation, extending the time needed for solidification, and increasing an activation rate of impurities. The substrate temperature can be set at a temperature that does not exceed the strain point of the base substrate.

In this embodiment, the n-type impurity semiconductor layers and the p-type Impurity semiconductor layers are formed in this order; however, the order may be reversed. In order to perform the process efficiently, a process may be used in which impurity semiconductor layers having one conductivity type is formed in a plurality of substrates in succession, and then impurity semiconductor layers having a conductivity type which is opposite to the one conductivity type are formed in the plurality of substrates in succession.

After that, the photoelectric conversion device can be formed according to another embodiment.

In this way, the stack which includes the insulating layer, the first single crystal semiconductor layer, and the second single crystal semiconductor layer over the base substrate is selectively irradiated with a laser beam in a gas atmosphere including an impurity serving as a dopant, whereby a plurality of impurity semiconductor layers which have different conductivity types can be formed in the surface layer of the single crystal semiconductor layer. In addition, in the case of selective laser beam irradiation, the position where the impurity semiconductor layers are formed can be determined; therefore, a positioning means of a photoresist, a protective film, or the like is unnecessary. Thus, the photoelectric conversion device with high productivity can be manufactured at low cost.

Note that this embodiment can be combined as appropriate with any of the other embodiments.

### Embodiment 7

In this embodiment, an example of a method for manufacturing a photoelectric conversion device, which is different from that described in the above embodiments, will be described. Note that a description of the same components as those of the above embodiment is omitted or partly simplified.

According to Embodiment 1, the stack including insulating layer 108, the first single crystal semiconductor layer 121, and the second single crystal semiconductor layer 122 is formed over the base substrate 110 (see FIG. 5B).

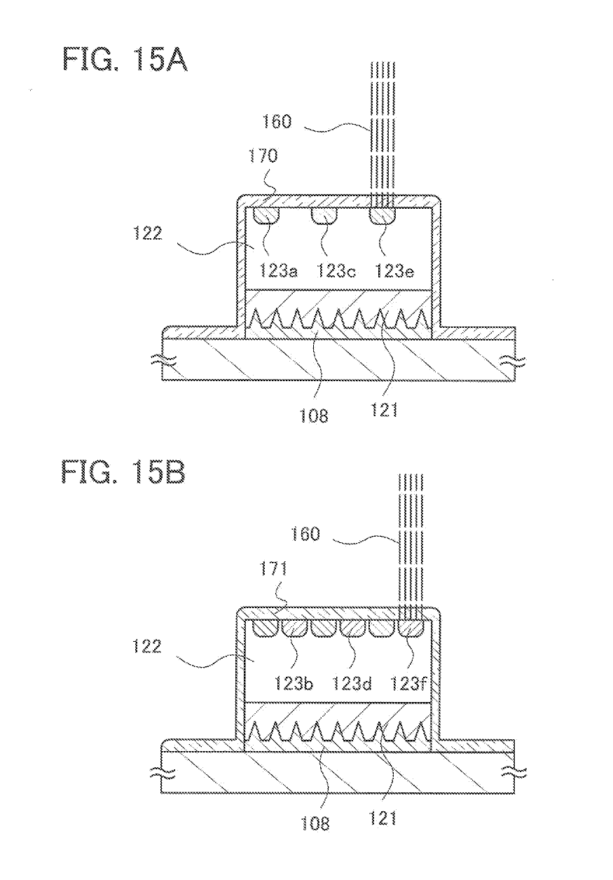

A chemical solution 170 including an impurity which imparts one conductivity type to a semiconductor and a chemical solution 171 including an impurity which imparts a conductivity type which is opposite to the one conductivity type to the semiconductor are applied to the upper surface of the stack, and a laser beam is selectively delivered, whereby impurity semiconductor layers are formed (see FIGS. 15A and 15B).

When the single crystal semiconductor layer is irradiated with a laser beam having a wavelength that is absorbed by the single crystal semiconductor layer, a phenomenon called melt-solidification occurs in the vicinity of the surface. This process of melting and solidifying is strongly affected by impurities attached to the surface and an impurity element attached to the surface is taken into the semiconductor layer which is melt. In this phenomenon, an impurity element taken into the semiconductor layer can change the conductivity type if the impurity element is a Group 13 element or a Group 15 element. Therefore, when this method is used, even if a specific apparatus such as an ion doping apparatus or an ion implantation apparatus is not used, the impurity can be introduced into the semiconductor layer,

Note that as the impurities which change the conductivity type of the semiconductor layer into n-type conductivity, phosphorus (P) which is a Group 15 element and boron (B) which is a Group 13 element can be typically given.

As a chemical solution including the above impurity elements, a phosphoric acid aqueous solution, trimethyl phosphate, triethyl phosphate, tri-n-amyl phosphate, diphenyl-2-ethylhexyl phosphate, an ammonium phosphate solution, a boric acid solution, trimethyl borate, triethyl borate, triisopropyl borate, tripropyl borate, tri-n-octyl borate, an ammonium borate solution, or the like can be used.

The above chemical solutions are aqueous solutions of salt or ester compounds which are hydrolyzed into a salt and alcohol, and can be easily cleaned only with pure water without specific cleaning fluid.

Specifically, when the impurity semiconductor layers which are formed first have n-type conductivity, an ammonium phosphate solution including an element serving as an n-type dopant is applied to the surface of the stack with a spin coater, a slit coater, or a dip coater, and then dried. Then, the semiconductor layer is irradiated with a laser beam having a band shape, so that the first impurity semiconductor layers 123a, 123c, and 123e are formed. After that, an ammonium borate solution which includes an element serving as a p-type dopant is applied to the surfaces of the stack with a spin coater, a slit coater, or a dip coater, and then dried. Then, the semiconductor layer is irradiated with a laser beam having a band shape, so that the second impurity semiconductor layers 123b, 123d, and 123f are formed. Further, cleaning with pure water is performed, and unnecessary impurities which are attached are washed away; thus, the structure illustrated in FIG. 7A is obtained.

As for a laser which can be used in this embodiment, the laser which is used for the recovery of crystallinity of the surface of the first single crystal semiconductor layer 121 in Embodiment 1 can be used.

Alternatively, as a means to promote melt-solidification by laser beam irradiation, a substrate may be heated with the heater for substrate heating. Heating a substrate has an effect of decreasing the melt threshold energy at the time of laser beam irradiation, extending the time needed for solidification, and increasing an activation rate of impurities. The substrate temperature can be set at a temperature that does not exceed the strain point of the base substrate.

In this embodiment, the n-type impurity semiconductor layers and the p-type impurity semiconductor layers are formed in this order; however, the order may be reversed. In order to perform the process efficiently, a process may be used in which impurity semiconductor layers having one conductivity type is formed in a plurality of substrates in succession, and then impurity semiconductor layers having a conductivity type which is opposite to the one conductivity type are formed in the plurality of substrates in succession.

After that, the photoelectric conversion device can be formed according to another embodiment.

In this way, the stack which includes the insulating layer, the first single crystal semiconductor layer, and the second single crystal semiconductor layer over the base substrate is coated with a chemical solution including an impurity serving as a dopant and then selectively irradiated with a laser beam, whereby a plurality of impurity semiconductor layers which have different conductivity types can be formed in the surface layer of the single crystal semiconductor layer. In addition, in the case of selective laser beam irradiation, the position where the impurity semiconductor layers are formed can be determined; therefore, a positioning means of a photoresist, a protective film, or the like is unnecessary. Thus, the photoelectric conversion device with high productivity can be manufactured at low cost.

Note that this embodiment can be combined as appropriate with any of the other embodiments.

### Example 1

In Example 1, an example in which a semiconductor layer including amorphous regions and a single crystal region is formed and then depressions are formed by etching will be described.

On surfaces of single crystal silicon wafers with a plane orientation of (100), semiconductor layers including amorphous regions and a single crystal semiconductor layer were formed by a plasma CVD method under the conditions shown in Table 1. The two deposition conditions in Table 1 are the same except that the RF power density is 0.1 W/cm² in Condition 1 whereas the RF power density is 0.3 W/cm² in Condition 2.

TABLE 1

| | | | | Frequency | | | |
|---|---|---|---|---|---|---|---|
| | | | | of power | Density of | Interval of | subtrate |
| | SiH₄ | H₂ | Pressure | source | power | electrodes | temperature |
| | sccm | | Pa | MHz | W/cm² | mm | ° C. |
| Condition (1) | 25 | 100 | 66.6 | 27 | 0.1 | 25 | 280 |
| Condition (2) | 25 | 100 | 66.6 | 27 | 0.3 | 25 | 280 |

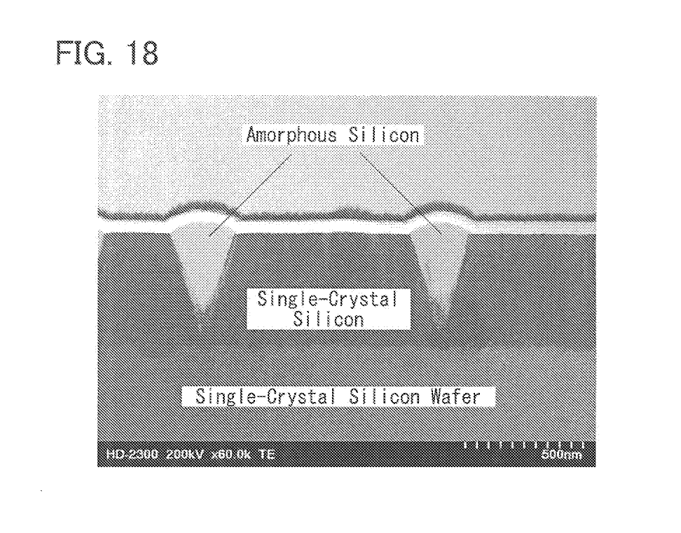

FIG. 18 is an electron microscope photograph of the sample formed under Condition 2 in Table 1. It can be seen that amorphous regions are formed in a single crystal layer epitaxially grown on the (100) single crystal silicon wafer. The amorphous region is grown to form the shape of a sector in the cross section from the vicinity of the interface of the single crystal silicon wafer. Note that the states of the single crystal region and the amorphous regions have been confirmed with electron-ray diffraction patterns.

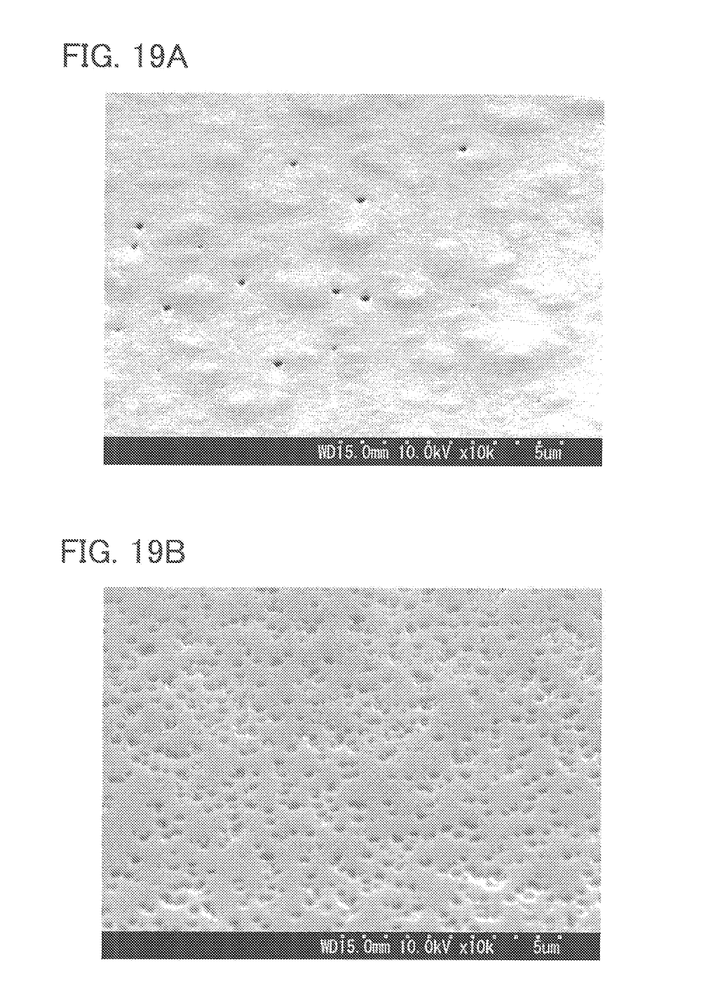

The samples which were formed under the conditions in Table 1 were etched with Secco etchant (a mixture solution of HF and K₂Cr₂O₇). FIGS. 19A and 19B are electron microscope photographs of the surfaces of the samples after the etching. FIG. 19A shows the sample of Condition 1 in Table 1; FIG. 19B shows the sample of Condition 2 in Table 1. When Secco etchant is used, the etching rate of the amorphous regions is higher than that of the single crystal region; thus, holes are formed in the single crystal layer. It can be seen that the shape of the hole at the surface of the single crystal layer is substantially circular and the hole density is higher in Condition 2 with a high RF power density at deposition than in Condition 1. As can be seen in the cross sectional shape in FIG. 18, the internal diameter of the hole decreases towards a lower portion of the film.

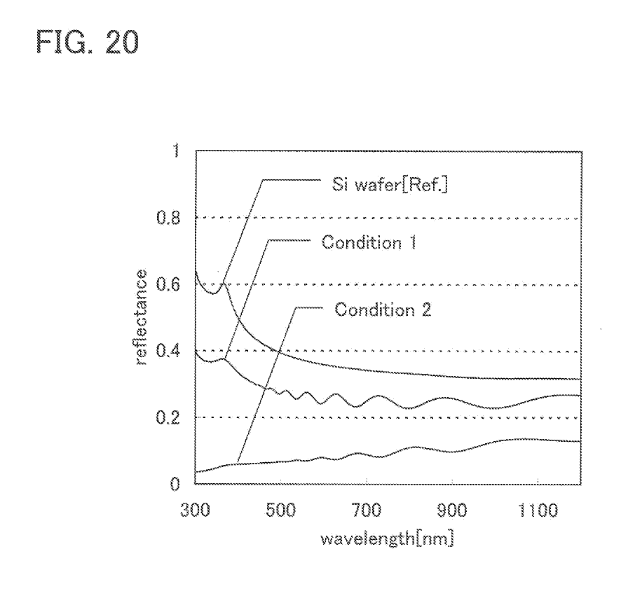

FIG. 20 is a graph showing spectral reflectance (regular reflectance) of the surfaces of the semiconductor layer shown in FIGS. 19A and 19B at a wavelength ranging from 300 nm to 1200 nm inclusive. The reflectance of a single crystal silicon wafer, which is given as a reference, is higher than 30% at a longer wavelength and is higher than 60% at a shorter wavelength, whereas the reflectance of the sample of Condition 2 with a high hole density is equal to or lower than 15% at a longer wavelength and is equal to or lower than 5% at a shorter wavelength. This shows that formation of holes can lower the reflectance. The result of the sample of Condition 1 with a low hole density lies between the two.

Thus, according to the results described in Example 1, it can be confirmed that when a semiconductor layer including amorphous regions and a single crystal semiconductor layer is formed on a single crystal silicon wafer by a plasma CVD method and depressions are formed by selective etching, a surface reflectance of the single crystal semiconductor layer is significantly reduced compared to a single crystal silicon wafer having a mirror surface. Therefore, it has been confirmed that by using a single crystal semiconductor layer having depressions in a photoelectric conversion device, a light-trapping effect is provided, whereby a highly efficient photoelectric conversion device can be formed.

This application is based on Japanese Patent Application serial no. 2009-189068 filed with Japan Patent Office on Aug. 18, 2009, the entire contents of which are hereby incorporated by reference.

What is claimed is:

1. A photoelectric conversion device comprising:
a light-transmitting base substrate;
an insulating layer over the light-transmitting base substrate;
a single crystal semiconductor layer over the insulating layer;
a first impurity semiconductor layer having a first conductivity type in a surface layer of the single crystal semiconductor layer;
a second impurity semiconductor layer which is adjacent to the first impurity semiconductor layer and does not overlap with the first impurity semiconductor layer, the second impurity semiconductor layer having a second conductivity type;
a first electrode over and in contact with the first impurity semiconductor layer; and
a second electrode over and in contact with the second impurity semiconductor layer,
wherein a plurality of depressions are formed on the single crystal semiconductor layer on a side where the single crystal semiconductor layer is in contact with the insulating layer, and
wherein the first conductivity type is opposite to the second conductivity type.

2. The photoelectric conversion device according to claim 1,
wherein the plurality of depressions formed on the single crystal semiconductor layer are filled with the insulating layer.

3. The photoelectric conversion device according to claim 1,
wherein the plurality of depressions are formed on the surface layer of the single crystal semiconductor layer.

4. The photoelectric conversion device according to claim 1,
wherein the plurality of depressions formed on the single crystal semiconductor layer have a circular shape at a surface of the single crystal semiconductor layer and an internal diameter which gradually decreases.

5. The photoelectric conversion device according to claim 1, further comprising a protective film,
wherein the protective film is provided over the single crystal semiconductor layer.

6. The photoelectric conversion device according to claim 5,
wherein the protective film is one selected from a silicon oxide layer, a silicon nitride layer, a silicon nitride oxide layer, and a silicon oxynitride layer.

7. A photoelectric conversion device comprising:
a light-transmitting base substrate;
an insulating layer over the light-transmitting base substrate;
a single crystal semiconductor layer over the insulating layer;
a first impurity semiconductor layer having a first conductivity type in a surface layer of the single crystal semiconductor layer;
a second impurity semiconductor layer which is adjacent to the first impurity semiconductor layer and does not overlap with the first impurity semiconductor layer, the second impurity semiconductor layer having a second conductivity type;
a first electrode over and in contact with the first impurity semiconductor layer; and
a second electrode over and in contact with the second impurity semiconductor layer,
wherein a first plurality of depressions are formed on the single crystal semiconductor layer on a first side where the single crystal semiconductor layer is in contact with the insulating layer,
wherein a second plurality of depressions are formed on the single crystal semiconductor layer on a second side where the first impurity semiconductor layer and the second impurity semiconductor layer are formed, and
wherein the first conductivity type is opposite to the second conductivity type.

8. The photoelectric conversion device according to claim 7,
wherein the first plurality of depressions formed on the single crystal semiconductor layer are filled with the insulating layer.

9. The photoelectric conversion device according to claim 7,
wherein the first plurality of depressions are formed on the surface layer of the single crystal semiconductor layer.

10. The photoelectric conversion device according to claim 7,
wherein the first plurality of depressions formed on the single crystal semiconductor layer have a circular shape at a surface of the single crystal semiconductor layer and an internal diameter which gradually decreases.

11. The photoelectric conversion device according to claim 7, further comprising a protective film,
wherein the protective film is provided over the single crystal semiconductor layer.

12. The photoelectric conversion device according to claim 11,
wherein the protective film is one selected from a silicon oxide layer, a silicon nitride layer, a silicon nitride oxide layer, and a silicon oxynitride layer.

13. A method for manufacturing a photoelectric conversion device, comprising the steps of:
irradiating a first single crystal semiconductor substrate with an ion to form an embrittlement layer in the first single crystal semiconductor substrate;
forming a semiconductor layer in contact with the first single crystal semiconductor substrate, the semiconductor layer including an amorphous region and a first single crystal semiconductor layer;
removing the amorphous region included in the semiconductor layer, whereby forming a second single crystal semiconductor substrate including a plurality of depressions;
forming an insulating layer over the second single crystal semiconductor substrate to fill the plurality of depressions for the insulating layer;
bonding the second single crystal semiconductor substrate to a base substrate with the insulating layer interposed therebetween;
dividing the second single crystal semiconductor substrate at the embrittlement layer to provide a stacked layer including the insulating layer and a second single crystal semiconductor layer in this order over the base substrate;
performing planarizing treatment on a surface of the second single crystal semiconductor layer;
forming a third single crystal semiconductor layer over the stacked layer;
forming a first impurity semiconductor layer having a first conductivity type in a surface layer of the third single crystal semiconductor layer;
forming a second impurity semiconductor layer which is adjacent to the first impurity semiconductor layer and does not overlap with the first impurity semiconductor layer, the second impurity semiconductor layer having a second conductivity type;
forming a first electrode over and in contact with the first impurity semiconductor layer; and
forming a second electrode over and in contact with the second impurity semiconductor layer,
wherein the first conductivity type is opposite to the second conductivity type.

14. The method for manufacturing a photoelectric conversion device according to claim 13,
wherein a plane orientation of the first single crystal semiconductor substrate is {100}.

15. The method for manufacturing a photoelectric conversion device according to claim 13,
wherein the semiconductor layer including the amorphous region and the first single crystal semiconductor layer is formed by a plasma CVD method.

16. The method for manufacturing a photoelectric conversion device according to claim 13,
wherein the planarizing treatment on the surface of the second single crystal semiconductor layer is performed by laser beam irradiation and/or etching.

17. The method for manufacturing a photoelectric conversion device according to claim 13,
wherein the insulating layer is one selected from a silicon oxide layer, a silicon nitride layer, a silicon nitride oxide layer, and a silicon oxynitride layer.

18. The method for manufacturing a photoelectric conversion device according to claim 13,
wherein the embrittlement layer is formed by introducing hydrogen, helium, or a halogen into the first single crystal semiconductor substrate.

19. A method for manufacturing a photoelectric conversion device, comprising the steps of:
irradiating a first single crystal semiconductor substrate with an ion to form an embrittlement layer in the first single crystal semiconductor substrate;
forming a first semiconductor layer in contact with the first single crystal semiconductor substrate, the first semiconductor layer including a first amorphous region and a first single crystal semiconductor layer to be;
removing the first amorphous region included in the first semiconductor layer, whereby forming a second single crystal semiconductor substrate including a first plurality of depressions;
forming an insulating layer over the second single crystal semiconductor substrate to fill the first plurality of depressions;
bonding the second single crystal semiconductor substrate to a base substrate with the insulating layer interposed therebetween;
dividing the second single crystal semiconductor substrate at the embrittlement layer to provide a first stacked layer including the insulating layer and a second single crystal semiconductor layer in this order over the base substrate;
performing planarizing treatment on a surface of the second single crystal semiconductor layer;
forming a third single crystal semiconductor layer over the first stacked layer;
forming a second semiconductor layer including a second amorphous region and a fourth single crystal semiconductor layer over the second single crystal semiconductor layer;
removing the second amorphous region included in the second semiconductor layer, whereby forming a second stacked layer including the first stacked layer, the third single crystal semiconductor layer, and the fourth single crystal semiconductor layer, wherein the second stacked layer includes a second plurality of depressions;
forming a first impurity semiconductor layer having a first conductivity type in a surface layer of the second stacked layer;
forming a second impurity semiconductor layer which is adjacent to the first impurity semiconductor layer and does not overlap with the first impurity semiconductor layer, the second impurity semiconductor layer having a second conductivity type;
forming a first electrode over and in contact with the first impurity semiconductor layer; and
forming a second electrode over and in contact with the second impurity semiconductor layer,
wherein the first conductivity type is opposite to the second conductivity type.

20. The method for manufacturing a photoelectric conversion device according to claim 19,
wherein a plane orientation of the first single crystal semiconductor substrate is {100}.

21. The method for manufacturing a photoelectric conversion device according to claim 19,
wherein the first semiconductor layer including the first amorphous region and the first single crystal semiconductor layer is formed by a plasma CVD method.

22. The method for manufacturing a photoelectric conversion device according to claim 19,
wherein the planarizing treatment on the surface of the second single crystal semiconductor layer is performed by laser beam irradiation and/or etching.

23. The method for manufacturing a photoelectric conversion device according to claim 19,
wherein the insulating layer is one selected from a silicon oxide layer, a silicon nitride layer, a silicon nitride oxide layer, and a silicon oxynitride layer.

24. The method for manufacturing a photoelectric conversion device according to claim 19,
wherein the embrittlement layer is formed by introducing hydrogen, helium, or a halogen into the first single crystal semiconductor substrate.
